(19) United States
(12) Patent Application Publication
(10) Pub. No.: US 2015/0355541 A1
(43) Pub. Date: Dec. 10, 2015

(54) ACTINIC-RAY- OR RADIATION-SENSITIVE RESIN COMPOSITION, ACTINIC-RAY- OR RADIATION-SENSITIVE FILM AND PATTERN FORMING METHOD

(71) Applicant: FUJIFILM CORPORATION, Tokyo (JP)

(72) Inventor: Kaoru IWATO, Shizuoka (JP)

(73) Assignee: FUJIFILM CORPORATION, Tokyo (JP)

(21) Appl. No.: 14/828,001

(22) Filed: Aug. 17, 2015

Related U.S. Application Data
(63) Continuation of application No. PCT/JP2014/053433, filed on Feb. 14, 2014.

(30) Foreign Application Priority Data
Feb. 19, 2013 (JP) 2013-030362

(51) Int. Cl. G03F 7/039; G03F 7/20; G03F 7/32; G03F 7/004

(52) U.S. Cl. CPC G03F 7/039; G03F 7/0045; G03F 7/20; G03F 7/32; G03F 7/2002; G03F 7/325

(57) ABSTRACT

An actinic-ray- or radiation-sensitive resin composition includes (A) a resin containing an acid-decomposable repeating unit and having a polarity that is changed when the resin is acted on by an acid, and (B) a compound that is configured to produce an acid when exposed to actinic rays or radiation. The acid produced by the compound (B) exhibits a Log P value of 3.0 or below and has a molecular weight of 430 or greater.

### CROSS-REFERENCE TO RELATED APPLICATIONS

This application is a Continuation application of PCT Application No. PCT/JP2014/053433, filed Feb. 14, 2014, and based upon and claiming the benefit of priority from Japanese Patent Application No. 2013-030362, filed Feb. 19, 2013, the entire contents of which are incorporated herein by reference.

### BACKGROUND OF THE INVENTION

1. Field of the Invention

The present invention relates to an actinic-ray- or radiation-sensitive resin composition that can find appropriate application in an ultramicrolithography process applicable to the manufacturing of a super-LSI or a high-capacity microchip, etc. and other photofabrication processes, and further relates to an actinic-ray- or radiation-sensitive film comprising the composition and a method of forming a pattern.

2. Description of the Related Art

In the process for manufacturing semiconductor devices, such as an IC and an LSI, the formation of an ultrafine pattern in the submicron region or quarter-micron region is increasingly required in accordance with the realization of high integration for integrated circuits.

The electron beam, X-ray or EUV light lithography is positioned as the next-generation or next-next-generation pattern forming technology. For the lithography, a resist composition of high sensitivity and high resolution is required.

In particular, increasing the sensitivity is a very important task to be attained for the shortening of wafer processing time. However, the pursuit of increasing the sensitivity is likely to invite deteriorations of pattern shape and resolution expressed by limiting resolved line width. Thus, there is a strong demand for the development of resist composition that can simultaneously satisfy these performances.

In the manufacturing of semiconductor devices and the like, not only positive but also negative actinic-ray- or radiation-sensitive resin compositions are being developed in order to meet the demand for the formation of patters with various shapes (see, for example, patent references 1 to 3).

However, especially in the pattern formation through the exposure to electron beams or extreme ultraviolet, the current situation is that discovering an appropriate combination of resist composition, developer, rinse liquid, etc. for the formation of a comprehensively favorable pattern is extremely difficult. Further improvement is required.

### CITATION LIST

### Patent Literature

Patent reference 1: Jpn. Pat. Appin. KOKAI Publication No. (hereinafter referred to as JP-A-) 2002-148806,

Patent reference 2: JP-A-2008-268935, and

Patent reference 3: JP-A-2012-220572.

### SUMMARY OF THE INVENTION

It is an object of the present invention to provide an actinic-ray- or radiation-sensitive resin composition capable of forming a pattern excelling in not only resolution but also line width roughness (LWR) and top roughness. It is another object of the present invention to provide an actinic-ray- or radiation-sensitive film comprising the above composition and to provide a method of forming a pattern. It is a further object of the present invention to provide a process for manufacturing an electronic device, in which the above pattern forming method is included, and to provide an electronic device manufactured by the process.

Embodiments of the present invention are as described below.

[1] An actinic-ray- or radiation-sensitive resin composition comprising:

(A) a resin containing an acid-decomposable repeating unit and having a polarity that is changed when the resin is acted on by an acid, and

(B) a compound that is configured to produce an acid when exposed to actinic rays or radiation,

wherein the acid produced by the compound (B) that is configured to produce an acid when exposed to actinic rays or radiation exhibits a Log P value of 3.0 or below and has a molecular weight of 430 or greater.

[2] The actinic-ray- or radiation-sensitive resin composition according to item [1], wherein the resin (A) further contains a repeating unit containing a polar group.

[3] The actinic-ray- or radiation-sensitive resin composition according to item [2], wherein the polar group is selected from among a hydroxyl group, a cyano group, a lactone group, a carboxylic acid group, a sulfonic acid group, an amide group, a sulfonamide group, an ammonium group, a sulfonium group and a group comprised of a combination of two or more of these.

[4] The actinic-ray- or radiation-sensitive resin composition according to item [1], wherein the resin (A) further contains a repeating unit containing an acid group.

[5] The actinic-ray- or radiation-sensitive resin composition according to item [4], wherein the acid group is any of a phenolic hydroxyl group, a carboxylic acid group, a sulfonic acid group, a fluoroalcohol group, a sulfonamide group, a sulfonylimide group, an (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group and a tris(alkylsulfonyl)methylene group.

[6] The actinic-ray- or radiation-sensitive resin composition according to item [1], wherein the resin (A) contains any of repeating units of general formula (I) below:

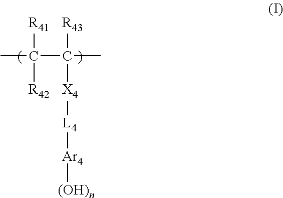

in which each of R₄₁, R₄₂ and R₄₃ independently represents a hydrogen atom, an alkyl group, a halogen atom, a cyano group or an alkoxycarbonyl group, provided that R₄₂ may be bonded to Ar₄ to thereby form a ring, which R₄₂ represents a single bond or an alkylene group;

X₄ represents a single bond, —COO— or —CONR₆₄— in which R₆₄ represents a hydrogen atom or an alkyl group;

L₄ represents a single bond or an alkylene group;

Ar₄ represents a (n+1)-valent aromatic ring group, provided that when Ar₄ is bonded to R₄₂ to thereby form a ring, Ar₄ represents a (n+2)-valent aromatic ring group; and

n is an integer of 1 to 4.

[7] The actinic-ray- or radiation-sensitive resin composition according to item [6], wherein the repeating units of general formula (I) are contained in the resin (A) in an amount of 4 mol % or less based on all the repeating units of the resin (A).

[8] The actinic-ray- or radiation-sensitive resin composition according to item [1], wherein the Log P value exhibited by the acid produced by the compound (B) is in the range of −2.0 to 1.5.

[9] An actinic-ray- or radiation-sensitive film comprising the actinic-ray- or radiation-sensitive resin composition of item [1].

[10] A method of forming a pattern, comprising forming a film comprising the composition of item [1], exposing the film to actinic rays or radiation, and developing the film having been exposed to actinic rays or radiation.

[11] The pattern forming method according to item [10], wherein the exposure to actinic rays or radiation is performed using electron beams or extreme ultraviolet.

[12] The pattern forming method according to item [10], wherein the development is performed with a developer comprising an organic solvent.

[13] The pattern forming method according to item [10], used to fabricate a semiconductor nanocircuit.

[14] A process for manufacturing an electronic device, comprising the pattern forming method of item [10].

[15] An electronic device manufactured by the process for manufacturing an electronic device according to item [14].

The present invention makes it feasible to provide an actinic-ray- or radiation-sensitive resin composition capable of forming a pattern excelling in not only resolution but also line width roughness (LWR) and top roughness. The present invention also makes it feasible to provide an actinic-ray- or radiation-sensitive film comprising the above composition and to provide a method of forming a pattern. Further, the present invention makes it feasible to provide a process for manufacturing an electronic device, in which the above pattern forming method is included, and to provide an electronic device manufactured by the process.

### DESCRIPTION OF THE INVENTION

The present invention will be described in detail below.

Herein, the term “group” or “atomic group” for which no statement is made as to substitution or nonsubstitution is to be interpreted as including not only one containing no substituent but also one containing a substituent. For example, the term “alkyl group” for which no statement is made as to substitution or nonsubstitution is to be interpreted as including not only an alkyl group containing no substituent (unsubstituted alkyl group) but also an alkyl group containing a substituent (substituted alkyl group).

In the present invention, the term “actinic rays” or “radiation” means, for example, brightline spectra from a mercury lamp, far ultraviolet represented by an excimer laser, extreme ultraviolet (EUV light), X-rays, particle beams such as electron beams and ion beams, or the like. In the present invention, the term “light” means actinic rays or radiation.

Moreover, herein, the term “exposure to light” unless otherwise specified means not only irradiation with light, such as a mercury lamp, far ultraviolet represented by an excimer laser, X-rays or extreme ultraviolet (EUV light), but also lithography using particle beams, such as electron beams and ion beams. In the present invention, the exposure to electron beams or extreme ultraviolet is preferred.

<Actinic-Ray- or Radiation-Sensitive Resin Composition>

First, the actinic-ray- or radiation-sensitive resin composition according to the present invention (hereinafter also referred to as “composition of the present invention” or “resist composition of the present invention”) will be described.

The composition of the present invention may be used in a negative development (namely, development in which exposed areas remain as a pattern while unexposed areas are removed, the development performed with a developer comprising an organic solvent), and also may be used in a positive development (namely, development in which exposed areas are removed while unexposed areas remain as a pattern, the development performed with an alkali developer).

The composition of the present invention is typically a resist composition. From the viewpoint of the realization of especially striking effects, it is preferred for the composition to be a negative resist composition. Further, the composition of the present invention is typically a chemically amplified resist composition. It is preferred for the composition of the present invention to be a composition that can be used in pattern formation in accordance with, for example, the method to be described hereinafter as “pattern forming method” and that can be used in a negative pattern forming method.

The actinic-ray- or radiation-sensitive resin composition of the present invention comprises [1] a resin (hereinafter also referred to as resin (A)) containing an acid-decomposable repeating unit and having a polarity that is changed when the resin is acted on by an acid, and [2] a compound (hereinafter also referred to as acid generator (B) or compound (B)) that is configured to produce an acid when exposed to actinic rays or radiation. The acid produced by acid generator (B) exhibits a Log P value of 3.0 or below, and the molecular weight (hereinafter also referred to as Mw) of the acid produced by the compound (B) is 430 or greater.

Further components that can be incorporated in the composition of the present invention include [3] a solvent, [4] a basic compound, [5] a surfactant and [6] other additive.

The composition of the present invention is capable of forming a pattern excelling in not only resolution (especially, isolated space resolution) but also line width roughness and top roughness. The following reason therefor can be presumed. When the acid produced by an acid generator has a small size and exhibits high hydrophobicity, the acid is likely to localize in resist and substrate surfaces due to the diffusion during post-exposure bake (PEB), thereby tending to bring about a non-uniform in-film distribution. In contrast, the acid produced by acid generator (B) according to the present invention has a large size (namely, molecular weight) and exhibits relatively low hydrophobicity. Therefore, it is presumed that when use is made of the composition of the present invention, the diffusion of acid during post-exposure bake (PEB) is uniformized to thereby lead to the formation of an excellent pattern.

The above-mentioned components will be sequentially described below.

[1] Resin (A)

The composition of the present invention comprises resin (A) containing an acid-decomposable repeating unit and having a polarity that is changed when the resin is acted on by an acid. Resin (A) is a resin whose solubility in a developer is changed (increased or decreased) by the action of an acid produced upon exposure to actinic rays or radiation. When a negative development with a developer comprising an organic solvent is intended, resin (A) is a resin whose polarity is increased by the action of an acid, so that the solubility in a developer comprising an organic solvent is decreased. When a positive development with an alkali developer is intended, resin (A) is a resin whose polarity is increased by the action of an acid, so that the solubility in an alkali developer is increased. In the present invention, it is preferred for resin (A) to be a resin whose solubility in a developer comprising an organic solvent is decreased by the action of an acid produced upon exposure to actinic rays or radiation. Repeating units that can be contained in resin (A) will be described below.

(a) Acid-Decomposable Repeating Unit

The acid-decomposable repeating unit refers to, for example, a repeating unit in which a group that is configured to decompose when acted on by an acid (hereinafter also referred to as “acid-decomposable group”) is introduced in the principal chain or a side chain of the resin, or both the principal chain and a side chain of the resin. It is preferred for the group produced by the decomposition to be a polar group from the viewpoint that the affinity to a developer comprising an organic solvent is lowered to thereby promote an insolubilization or a realization of poor solubility (negativation). Further, it is preferred for the polar group to be an acid group. The definition of the polar group is the same as to be described hereinafter in connection with repeating unit (b). Examples of polar groups produced by the decomposition of the acid-decomposable group include an alcoholic hydroxyl group, an amino group and an acid group.

It is preferred for the polar group produced by the decomposition of the acid-decomposable group to be an acid group.

When an organic developer is used as the developer, the acid group is not particularly limited as long as it is a group insolubilized in a developer comprising an organic solvent. For example, there can be mentioned groups set forth as examples of alkali-soluble groups in section [0037] of JP-A-2012-208447 (WO 2012-133939).

A preferred form of acid-decomposable group is one resulting from the replacement of a hydrogen atom of the acid-decomposable group by a group leaving in an acid.

As the group leaving in an acid, there can be mentioned, for example, any of groups set forth in sections [0040] to [0042] of JP-A-2012-208447.

It is preferred for the acid-decomposable group to be a cumyl ester group, an enol ester group, an acetal ester group, a tertiary alkyl ester group or the like. A tertiary alkyl ester group is more preferred.

Repeating unit (a) is preferably any of repeating units of general formula (V) below.

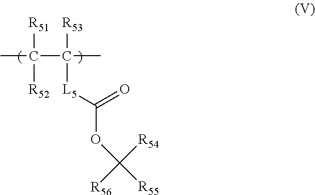

In general formula (V),

each of R₅₁, R₅₂ and R₅₃ independently represents a hydrogen atom, an alkyl group, a cycloalkyl group, a halogen atom, a cyano group or an alkoxycarbonyl group. R₅₂ may be bonded to L₅ to thereby form a ring, which R₅₂ represents an alkylene group.

L₅ represents a single bond or a bivalent connecting group. When a ring is formed in cooperation with R₅₂, L₅ represents a trivalent connecting group.

R₅₄ represents an alkyl group, and each of R₅₅ and R₅₆ independently represents a hydrogen atom, an alkyl group, a cycloalkyl group, a monovalent aromatic ring group or an aralkyl group. R₅₅ and R₅₆ may be bonded to each other to thereby form a ring, provided that R₅₅ and R₅₆ are not simultaneously hydrogen atoms.

The alkyl group represented by each of R₅₄ to R₅₆ is preferably one having 1 to 20 carbon atoms, more preferably one having 1 to 10 carbon atoms and most preferably one having 1 to 4 carbon atoms, such as a methyl group, an ethyl group, an n-propyl group, an isopropyl group, an n-butyl group, an isobutyl group or a t-butyl group.

The cycloalkyl group represented by each of R₅₅ and R₅₆ is preferably one having 3 to 20 carbon atoms. It may be a monocyclic one, such as a cyclopentyl group or a cyclohexyl group, or a polycyclic one, such as a norbonyl group, an adamantyl group, a tetracyclodecanyl group or a tetracyclododecanyl group.

The ring formed by the mutual bonding of R₅₅ and R₅₆ preferably has 3 to 20 carbon atoms. It may be a monocyclic one, such as a cyclopentyl group or a cyclohexyl group, or a polycyclic one, such as a norbonyl group, an adamantyl group, a tetracyclodecanyl group or a tetracyclododecanyl group. When R₅₅ and R₅₆ are bonded to each other to thereby form a ring, R₅₄ is preferably an alkyl group having 1 to 3 carbon atoms, more preferably a methyl group or an ethyl group.

The monovalent aromatic ring group represented by each of R₅₅ and R₅₆ is preferably one having 6 to 20 carbon atoms. The monovalent aromatic ring group may be monocyclic or polycyclic, and a substituent may be introduced therein.

As such, there can be mentioned, for example, a phenyl group, a 1-naphthyl group, a 2-naphthyl group, a 4-methylphenyl group, a 4-methoxyphenyl group or the like. When either R₅₅ or R₅₆ is a hydrogen atom, it is preferred for the other to be a monovalent aromatic ring group.

The aralkyl group represented by each of R₅₅ and R₅₆ may be monocyclic or polycyclic, and a substituent may be introduced therein. The aralkyl group preferably has 7 to 21 carbon atoms, and as such, there can be mentioned a benzyl group, a 1-naphthylmethyl group or the like.

Specific examples of repeating units (a) of general formula (V) are shown below, which in no way limit the present invention.

In the specific examples, each of Rx and Xa₁ represents a hydrogen atom, CH₃, CF₃ or CH₂OH. Each of Rxa and Rxb independently represents an alkyl group having 1 to 4 carbon atoms, an aryl group having 6 to 18 carbon atoms or an aralkyl group having 7 to 19 carbon atoms. Z represents a substituent; and p is 0 or a positive integer, preferably 0 to 2 and more preferably 0 or 1.

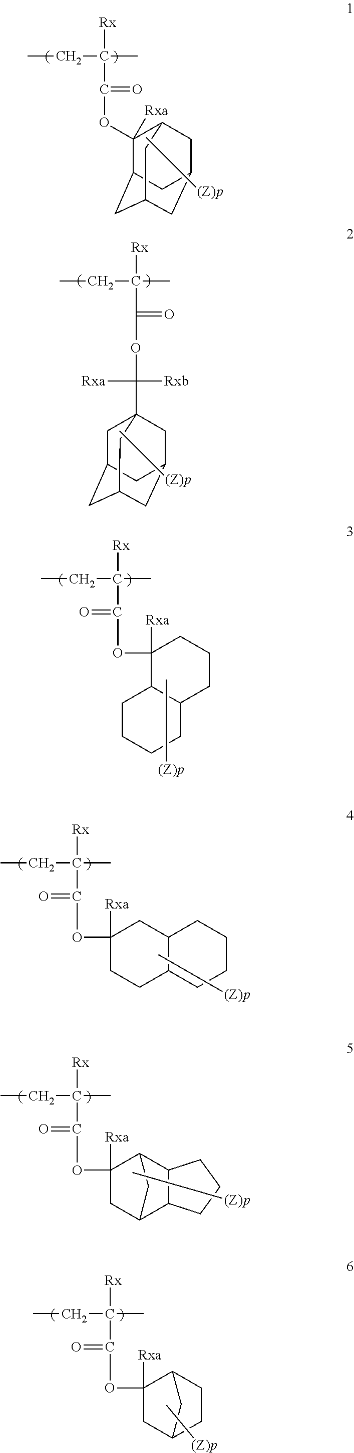

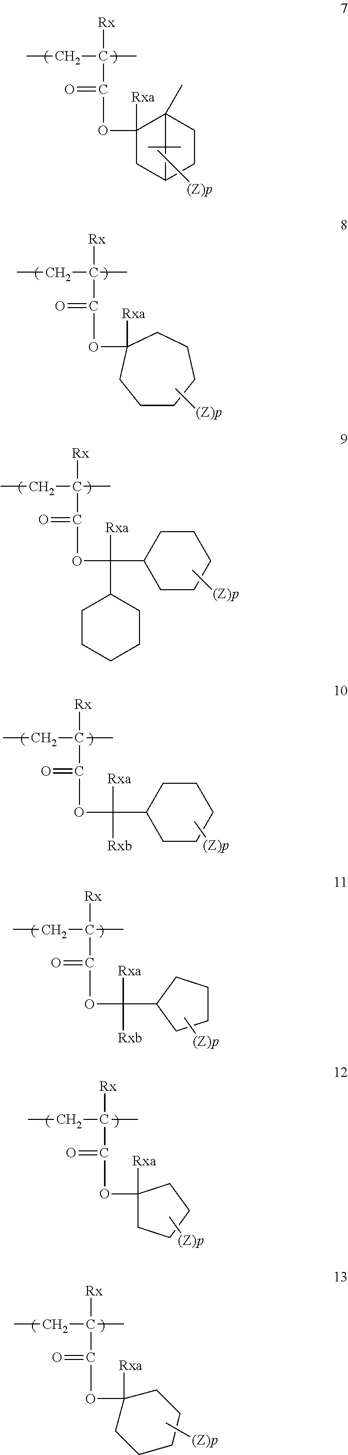

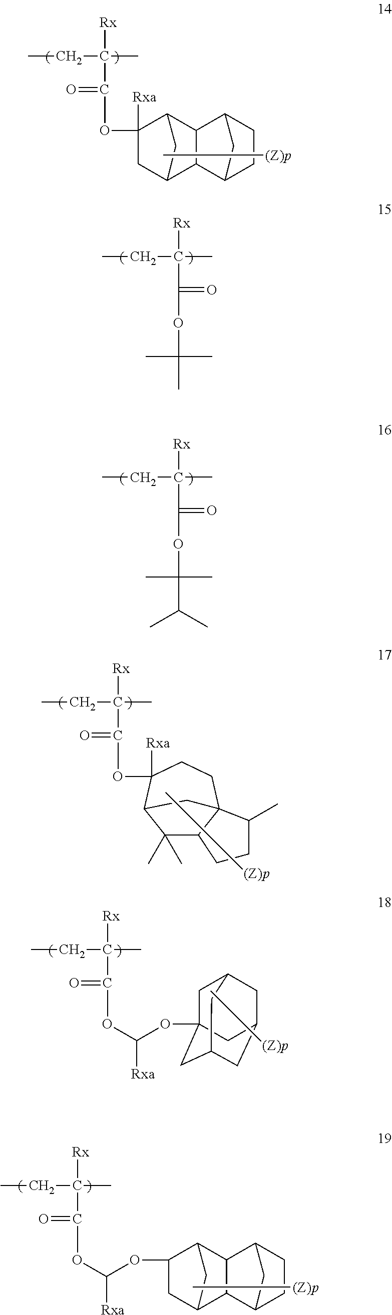

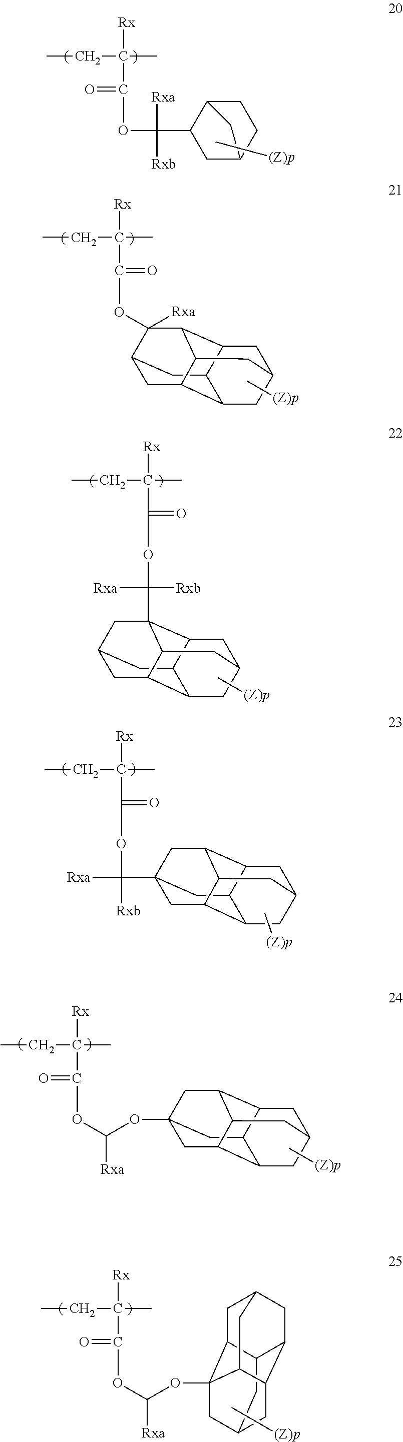

Resin (A) may contain any of repeating units of general formula (VI) below as repeating unit (a).

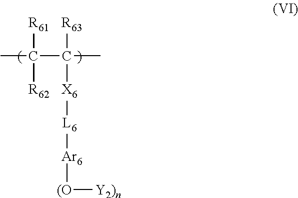

In general formula (VI),

each of R₆₁, R₆₂ and R₆₃ independently represents a hydrogen atom, an alkyl group, a cycloalkyl group, a halogen atom, a cyano group or an alkoxycarbonyl group, provided that R₆₂ may be bonded to Ar₆ to thereby form a ring, which R₆₂ represents a single bond or an alkylene group.

X₆ represents a single bond, —COO— or —CONR₆₄— in which R₆₄ represents a hydrogen atom or an alkyl group.

L₆ represents a single bond or an alkylene group.

Ar₆ represents a (n+1)-valent aromatic ring group. When Ar₆ is bonded to R₆₂ to thereby form a ring, Ar₆ represents a (n+2)-valent aromatic ring group.

Y₂, when n≧2 each independently, represents a hydrogen atom or a group leaving under the action of an acid, provided that at least one of Y₂s is a group leaving under the action of an acid; and

n is an integer of 1 to 4.

X₆ is preferably a single bond, —COO— or —CONH—, more preferably a single bond or —COO—.

The alkylene group represented by L₆ is preferably an optionally substituted alkylene group having 1 to 8 carbon atoms, such as a methylene group, an ethylene group, a propylene group, a butylene group, a hexylene group or an octylene group. The ring formed by the mutual bonding of R₆₂ and L₆ is most preferably a 5- or 6-membered ring.

Ar₆ represents a (n+1)-valent aromatic ring group. A substituent may be introduced in the bivalent aromatic ring group in which n is 1. As preferred examples thereof, there can be mentioned an arylene group having 6 to 18 carbon atoms, such as a phenylene group, a tolylene group or a naphthylene group, and a bivalent aromatic ring group containing a heteroring, such as thiophene, furan, pyrrole, benzothiophene, benzofuran, benzopyrrole, triazine, imidazole, benzimidazole, triazole, thiadiazole or triazole.

As preferred particular examples of the (n+1)-valent aromatic ring groups in which n is an integer of 2 or greater, there can be mentioned groups resulting from the removal of (n−1) arbitrary hydrogen atoms from each of the above-mentioned particular examples of bivalent aromatic ring groups.

Further substituents may be introduced in these (n+1)-valent aromatic ring groups.

In the formula, n is preferably 1 or 2, more preferably 1.

Each of n Y₂s independently represents a hydrogen atom or a group leaving under the action of an acid, provided that at least one of n Y₂s represents a group leaving under the action of an acid.

As the group leaving under the action of an acid, Y₂, there can be mentioned, for example, —C(R₃₆)(R₃₇)(R₃₈), —C(═O)—O—C(R₃₆)(R₃₇)(R₃₈), —C(R₀₁)(R₀₂)(OR₃₉), —C(R₀₁)(R₀₂)—C(═O)—O—C(R₃₆)(R₃₇)(R₃₈), —CH(R₃₆)(Ar) or the like.

In the formulae, each of R₃₆ to R₃₉ independently represents an alkyl group, a cycloalkyl group, a monovalent aromatic ring group, a group composed of a combination of an alkylene group and a monovalent aromatic ring group, or an alkenyl group. R₃₆ and R₃₇ may be bonded to each other to thereby form a ring.

Each of R₀₁ and R₀₂ independently represents a hydrogen atom, an alkyl group, a cycloalkyl group, a monovalent aromatic ring group, a group composed of a combination of an alkylene group and a monovalent aromatic ring group, or an alkenyl group.

Ar represents a monovalent aromatic ring group.

The group leaving under the action of an acid, Y₂, preferably has any of the structures of general formula (VI-A) below.

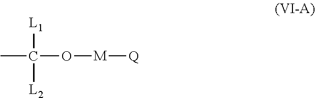

In the formula, each of L₁ and L₂ independently represents a hydrogen atom, an alkyl group, a cycloalkyl group, a monovalent aromatic ring group or a group comprised of an alkylene group combined with a monovalent aromatic ring group.

M represents a single bond or a bivalent connecting group.

Q represents an alkyl group, a cycloalkyl group optionally containing a heteroatom, a monovalent aromatic ring group optionally containing a heteroatom, an amino group, an ammonium group, a mercapto group, a cyano group or an aldehyde group.

At least two of Q, M and L₁ may be bonded to each other to thereby form a ring (preferably, a 5-membered or 6-membered ring).

The alkyl groups represented by L₁ and L₂ are, for example, alkyl groups each having 1 to 8 carbon atoms. As preferred examples thereof, there can be mentioned a methyl group, an ethyl group, a propyl group, an n-butyl group, a sec-butyl group, a hexyl group and an octyl group.

The cycloalkyl groups represented by L₁ and L₂ are, for example, cycloalkyl groups each having 3 to 15 carbon atoms. As preferred examples thereof, there can be mentioned a cyclopentyl group, a cyclohexyl group, a norbornyl group, an adamantyl group and the like.

The monovalent aromatic ring groups represented by L₁ and L₂ are, for example, aryl groups each having 6 to 15 carbon atoms. As preferred examples thereof, there can be mentioned a phenyl group, a tolyl group, a naphthyl group, an anthryl group and the like.

The groups each comprised of an alkylene group combined with a monovalent aromatic ring group, represented by L₁ and L₂ are, for example, those each having 6 to 20 carbon atoms. There can be mentioned aralkyl groups, such as a benzyl group and a phenethyl group.

The bivalent connecting group represented by M is, for example, an alkylene group (e.g., a methylene group, an ethylene group, a propylene group, a butylene group, a hexylene group, an octylene group, etc.), a cycloalkylene group (e.g., a cyclopentylene group, a cyclohexylene group, an adamantylene group, etc.), an alkenylene group (e.g., an ethylene group, a propenylene group, a butenylene group, etc.), a bivalent aromatic ring group (e.g., a phenylene group, a tolylene group, a naphthylene group, etc.), —S—, —O—, —CO—, —SO₂—, —N(R₀)— or a bivalent connecting group resulting from combination of these groups. R₀ represents a hydrogen atom or an alkyl group (for example, an alkyl group having 1 to 8 carbon atoms; in particular, a methyl group, an ethyl group, a propyl group, an n-butyl group, a sec-butyl group, a hexyl group, an octyl group or the like).

The alkyl group represented by Q is the same as mentioned above as being represented by each of L₁ and L₂.

As the aliphatic hydrocarbon ring group containing no heteroatom and monovalent aromatic ring group containing no heteroatom respectively contained in the cycloalkyl group optionally containing a heteroatom and monovalent aromatic ring group optionally containing a heteroatom, both represented by Q, there can be mentioned, for example, the cycloalkyl group and monovalent aromatic ring group mentioned above as being represented by each of L₁ and L₂. Preferably, each thereof has 3 to 15 carbon atoms.

As the cycloalkyl group containing a heteroatom and monovalent aromatic ring group containing a heteroatom, there can be mentioned, for example, groups with a heterocyclic structure, such as thiirane, cyclothiorane, thiophene, furan, pyrrole, benzothiophene, benzofuran, benzopyrrole, triazine, imidazole, benzimidazole, triazole, thiadiazole, triazole and pyrrolidone. However, the above cycloalkyl groups and monovalent aromatic ring groups are not limited to these as long as a structure generally known as a heteroring (ring formed by carbon and a heteroatom, or ring formed by heteroatoms) is included.

As the ring that may be formed by the mutual bonding of at least two of Q, M and L₁, there can be mentioned one resulting from the mutual bonding of at least two of Q, M and L₁ so as to form, for example, a propylene group or a butylene group, thereby forming a 5-membered or 6-membered ring containing the oxygen atom.

Substituents may be introduced in the groups represented by L₁, L₂, M and Q in general formula (VI-A). Preferably, the number of carbon atoms of each of the substituents is up to 8.

The groups of the formula -M-Q are preferably groups each composed of 1 to 30 carbon atoms, more preferably 5 to 20 carbon atoms.

Particular examples of the repeating units of general formula (VI) are shown below as preferred particular examples of repeating units (a), which in no way limit the present invention.

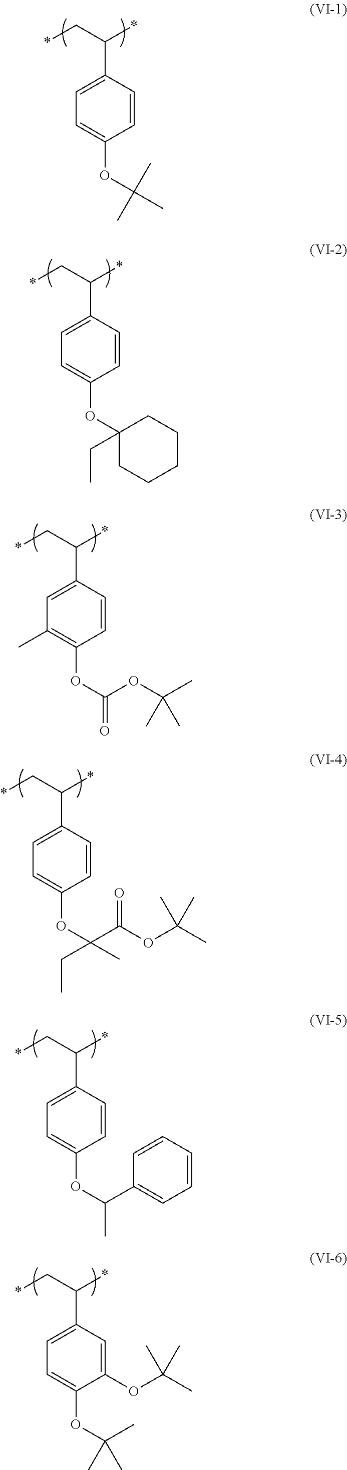

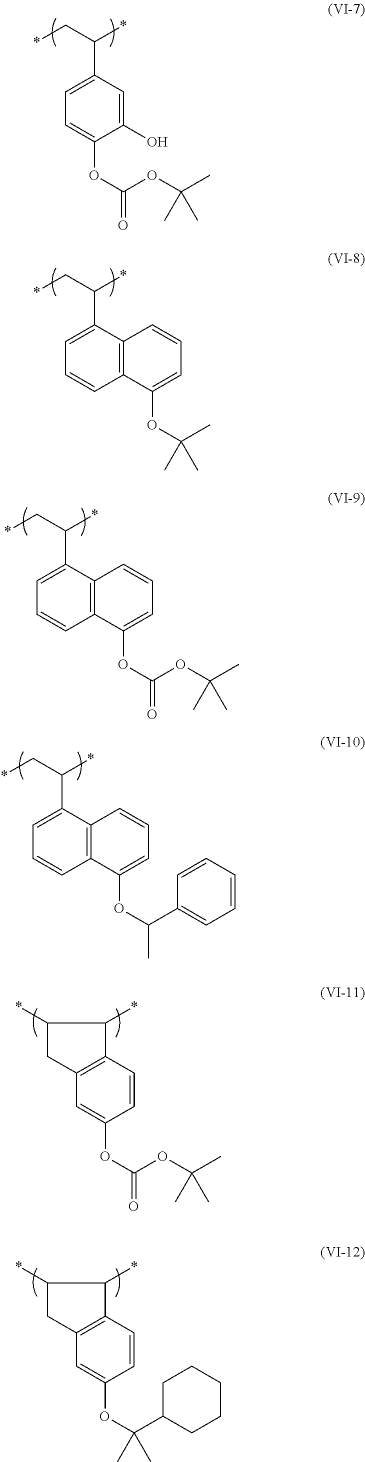

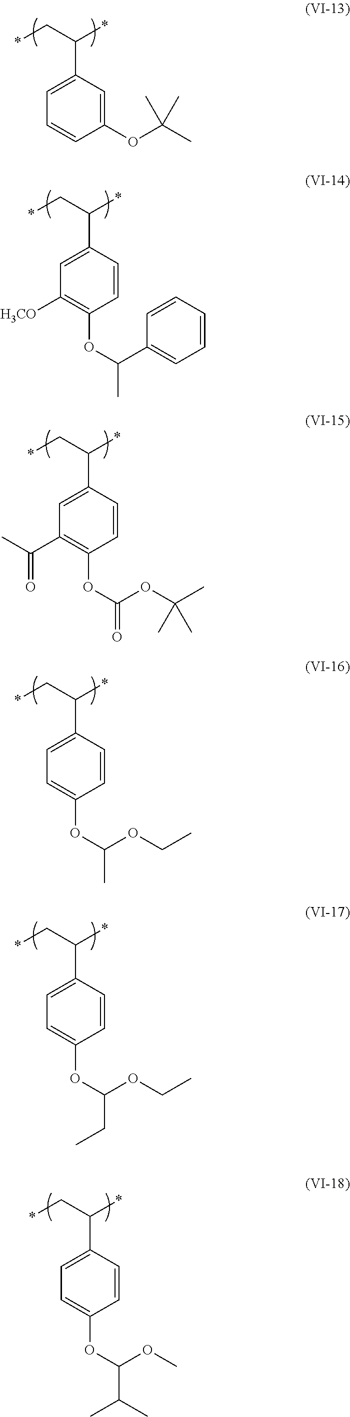

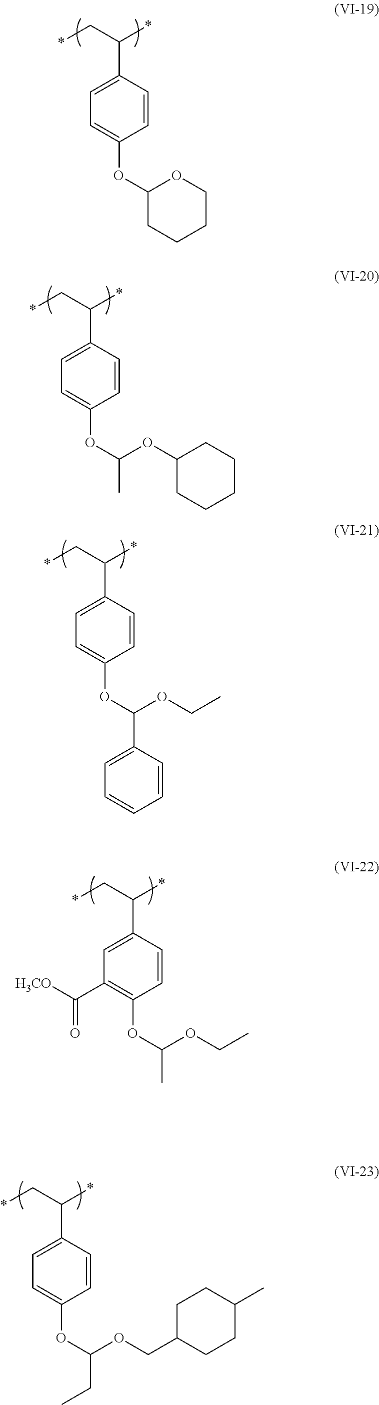

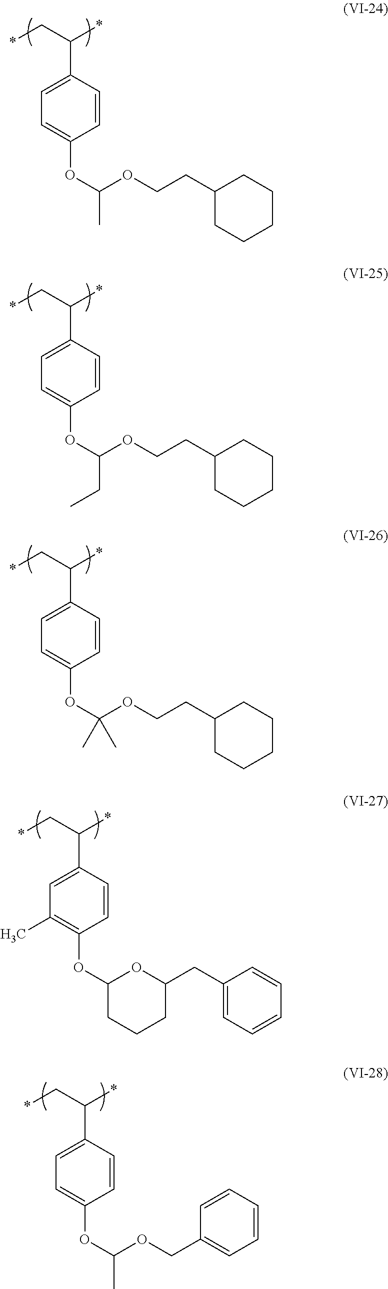

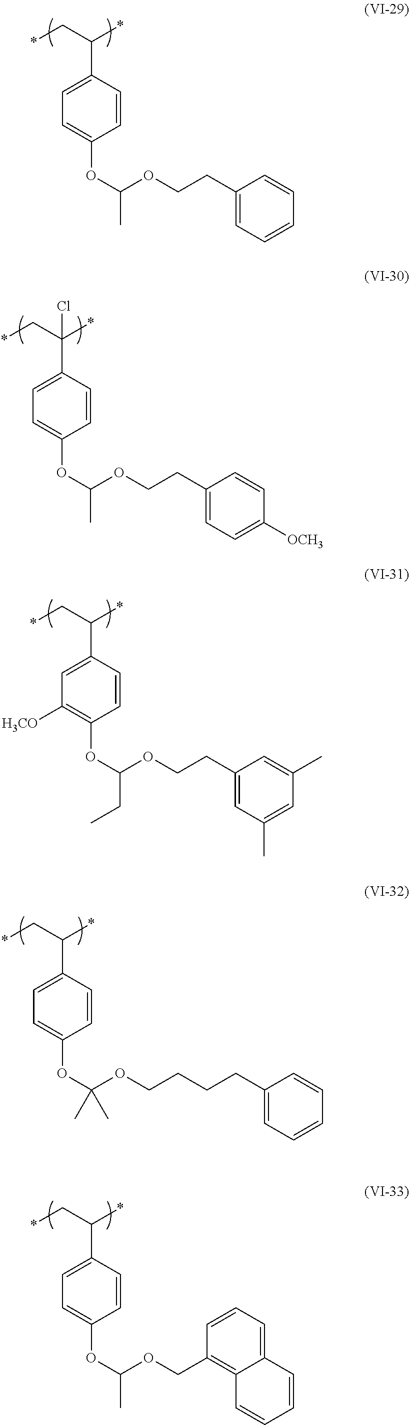

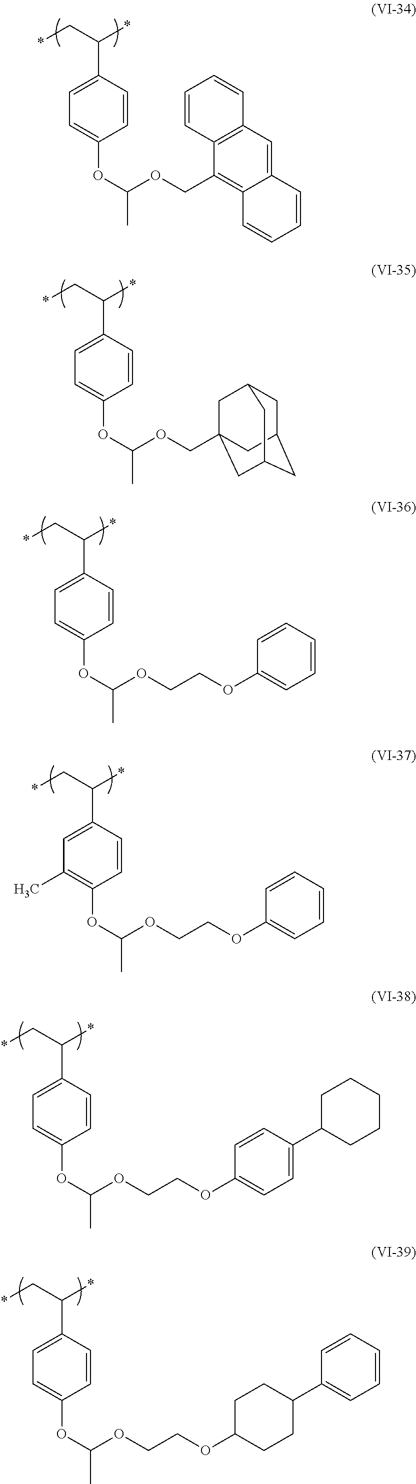

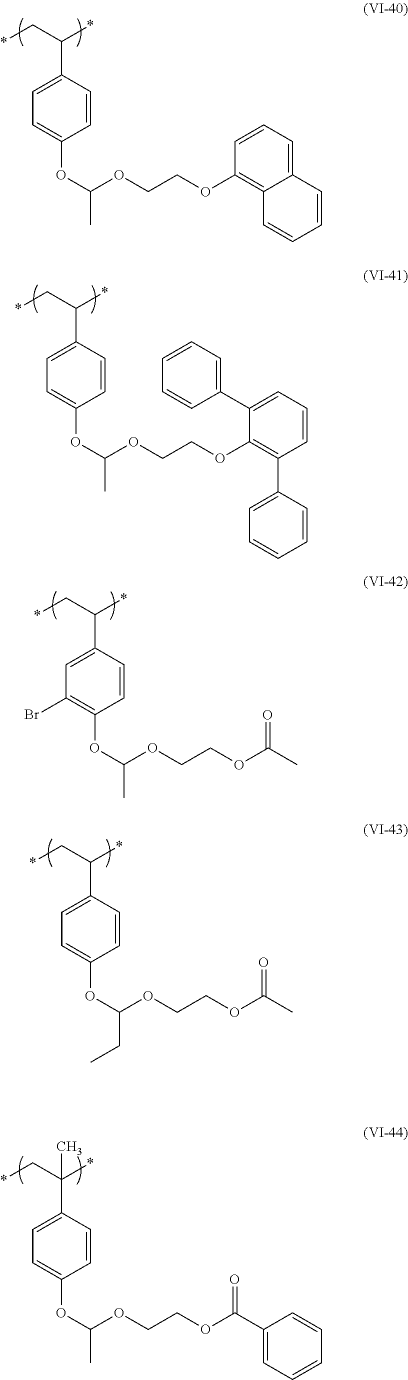

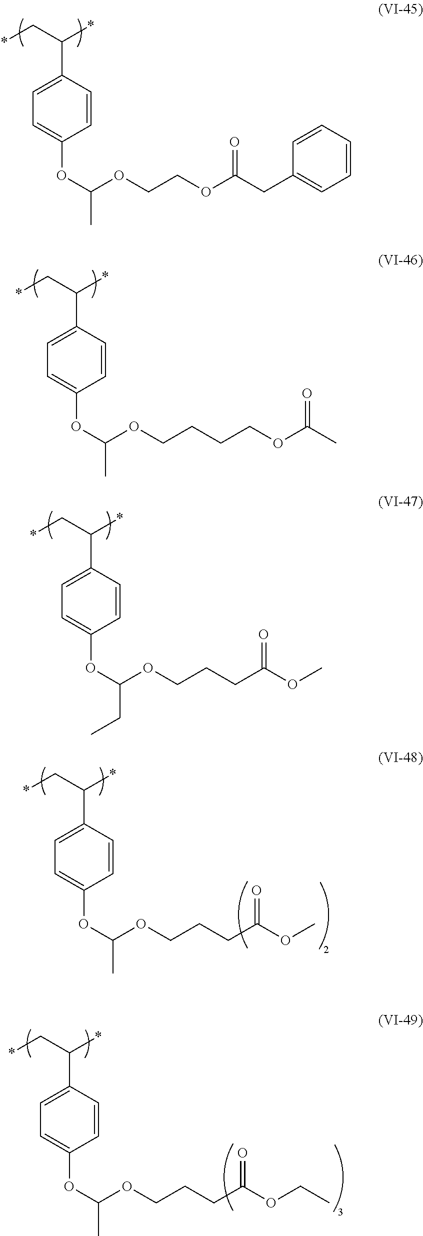

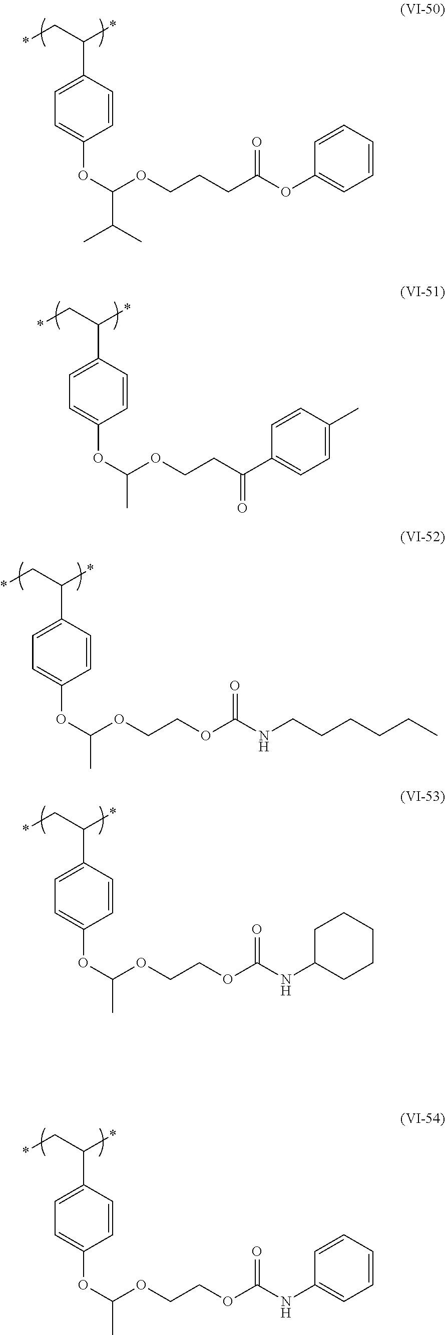

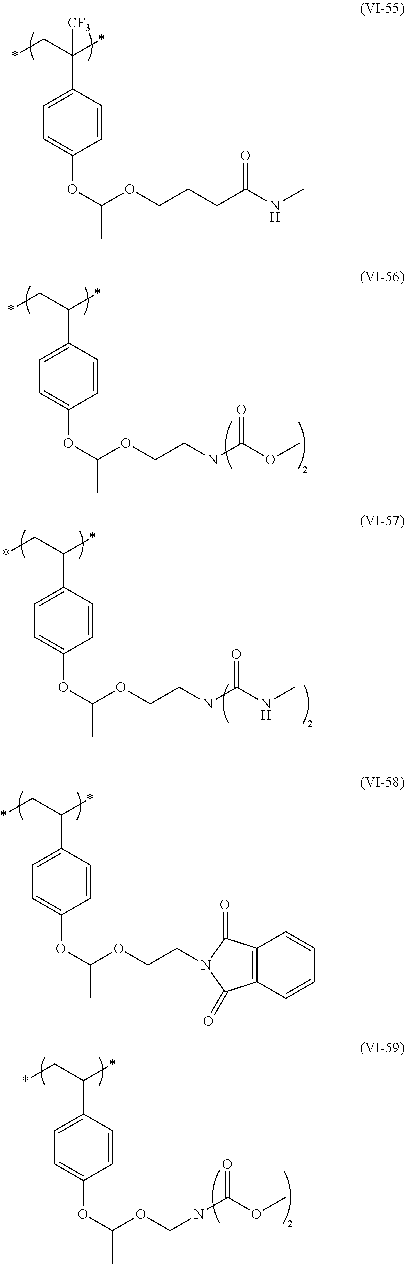

The repeating units of general formula (VI) are repeating units capable of producing a phenolic hydroxyl group through the decomposition of an acid-decomposable group. The use thereof tends to fail to render the solubility of the resin at areas exposed to light in an organic solvent satisfactorily low, so that there are occasions in which it is preferred not to incorporate the same in a large amount from the viewpoint of resolution. This tendency is magnificent in the use of repeating units derived from hydroxystyrenes (namely, those of general formula (VI) in which both X₆ and L₆ are single bonds). The reason therefor has not been elucidated. However, it can be presumed that the reason is, for example, the presence of a phenolic hydroxyl group in the vicinity of the principal chain. Therefore, in the present invention, the content of repeating unit capable of producing a phenolic hydroxyl group through the decomposition of an acid-decomposable group (for example, repeating units of general formula (VI) above, preferably repeating units of general formula (VI) in which both X₆ and L₆ are single bonds), based on all the repeating units of resin (A), is preferably 4 mol % or less, more preferably 2 mol % or less and most preferably 0 mol % (namely none contained).

Resin (A) may contain repeating units of general formula (BZ) described in section [0101] of JP-A-2012-208447 as repeating units (a). The definition and specific examples of employed groups are the same as set forth in sections [0101] to [0132] of JP-A-2012-208447.

A form of repeating unit containing an acid-decomposable group that is different from the repeating units set forth above by way of example may be a form of repeating unit capable of producing an alcoholic hydroxyl group. This form is preferably expressed by at least one member selected from the group consisting of general formulae (1-1) to (1-10) shown in section [0233] of JP-A-2011-248019 (WO 2011-149035). The definition and specific examples of groups employed in general formulae (1-1) to (1-10) are as set forth in sections [0233] to [0252] of JP-A-2011-248019.

Groups configured to decompose when acted on by an acid to thereby produce an alcoholic hydroxyl group are preferably expressed by at least one member selected from the group consisting of general formulae (1I-1) to (1I-4) shown in section [0253] of JP-A-2011-248019. The definition of each of groups employed in general formulae (1I-1) to (1I-4) is as set forth in sections [0253] and [0254] of JP-A-2011-248019.

Groups configured to decompose when acted on by an acid to thereby produce an alcoholic hydroxyl group are also preferably expressed by at least one member selected from the group consisting of general formulae (1I-5) to (1I-9) shown in section [0255] of JP-A-2011-248019. The definition of each of groups employed in general formulae (1I-5) to (1I-9) is as set forth in sections [0256] to [0265] of JP-A-2011-248019.

Specific examples of the groups configured to decompose when acted on by an acid to thereby produce an alcoholic hydroxyl group are as shown in sections [0266] and [0267] of JP-A-2011-248019.

Particular examples of the repeating units containing groups configured to decompose when acted on by an acid to thereby produce an alcoholic hydroxyl group are shown below. In the following particular examples, Xa₁ represents a hydrogen atom, CH₃, CF₃ or CH₂OH.

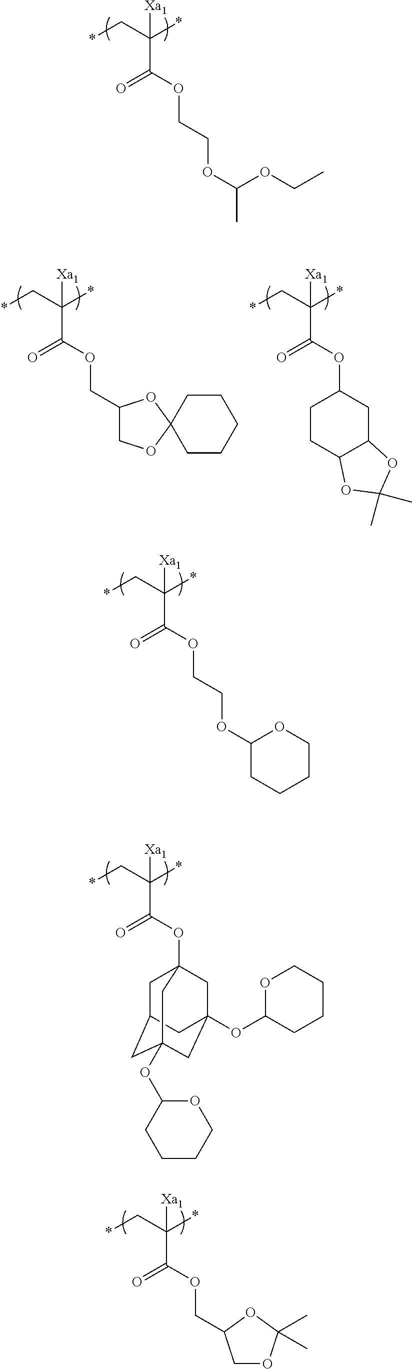

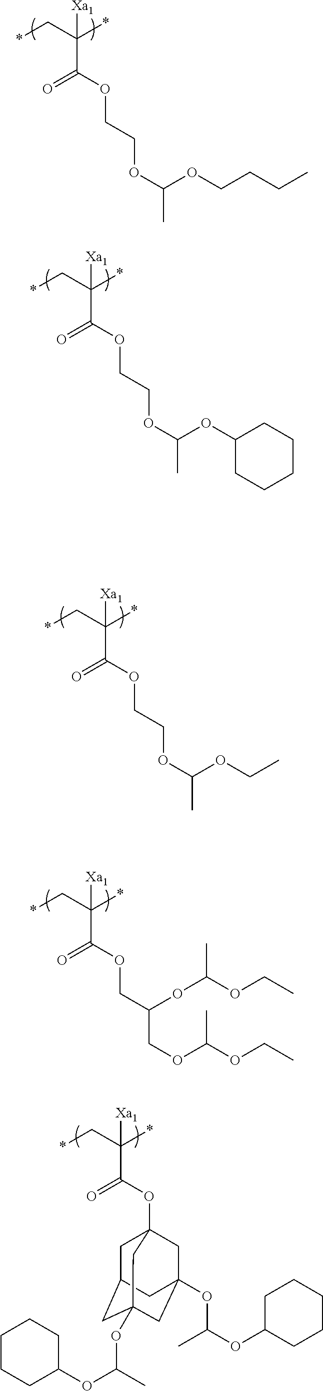

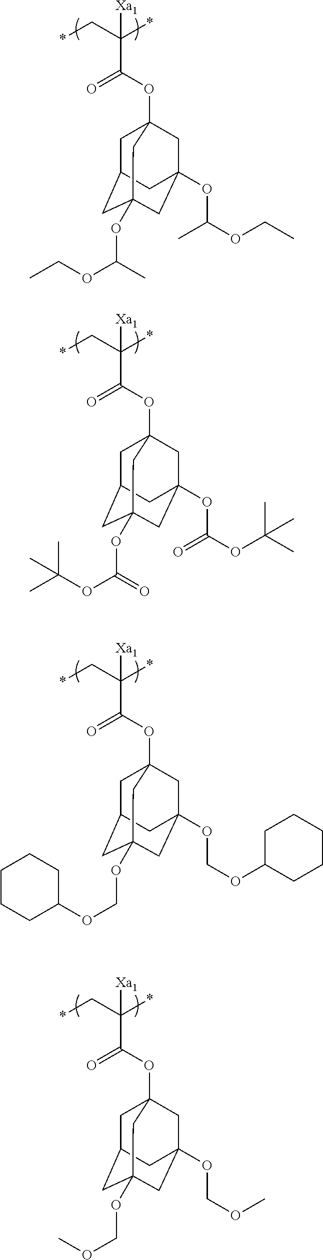

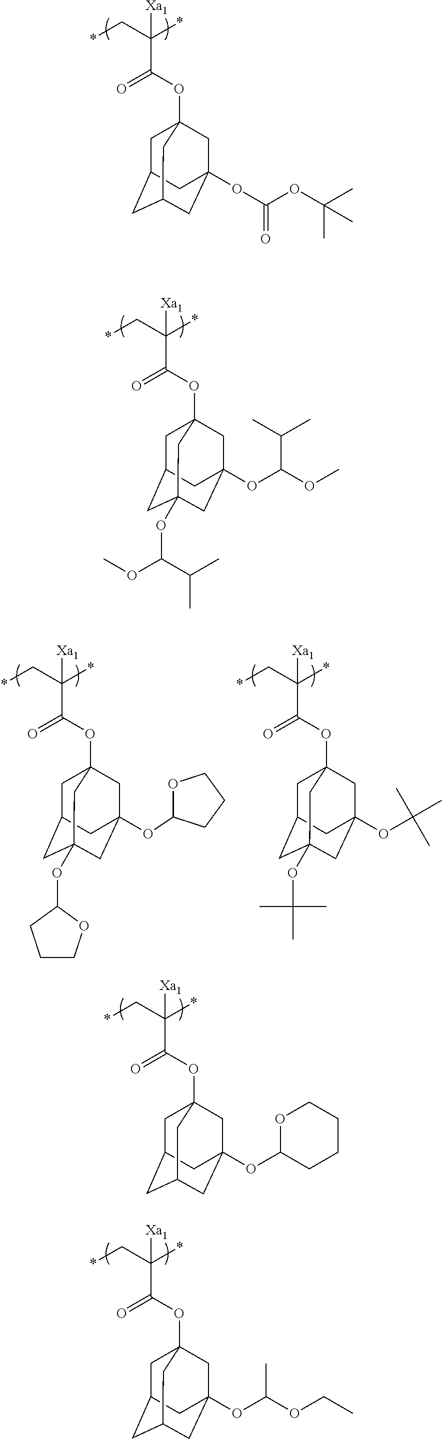

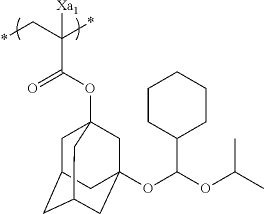

One of the above repeating units each containing an acid-decomposable group may be used alone, or two or more thereof may be used in combination.

The content of repeating unit containing an acid-decomposable group in resin (A) (when a plurality of repeating units are contained, the sum thereof), based on all the repeating units of resin (A), is preferably in the range of 5 to 80 mol %, more preferably 5 to 75 mol % and further more preferably 10 to 65 mol %.

(b) Repeating Unit Containing a Polar Group

Resin (A) preferably contains a repeating unit (b) containing a polar group. For example, the sensitivity of compositions comprising the resin can be enhanced by containing repeating unit (b). It is preferred for repeating unit (b) to be a non-acid-decomposable repeating unit (namely, containing no acid-decomposable group).

As the “polar group” that can be contained in repeating unit (b), there can be mentioned, for example, the following (1) to (4). In the following, “electronegativity” means a value defined by Pauling.

(1) Functional group containing a structure in which an oxygen atom is bonded through a single bond to an atom whose electronegativity exhibits a difference of 1.1 or greater from that of the oxygen atom.

As this polar group, there can be mentioned, for example, a group containing the structure of 0-H, such as a hydroxyl group.

(2) Functional group containing a structure in which a nitrogen atom is bonded through a single bond to an atom whose electronegativity exhibits a difference of 0.6 or greater from that of the nitrogen atom.

As this polar group, there can be mentioned, for example, a group containing the structure of N—H, such as an amino group.

(3) Functional group containing a structure in which two atoms whose electronegativity values exhibit a difference of 0.5 or greater are bonded to each other through a double bond or triple bond.

As this polar group, there can be mentioned, for example, a group containing the structure of CN, C═O, N═O, S═O or C═N.

(4) Functional group containing an ionic moiety.

As this polar group, there can be mentioned, for example, a group containing the moiety of N⁺ or S⁺.

Particular examples of partial structures that can be contained in the “polar group” are shown below.

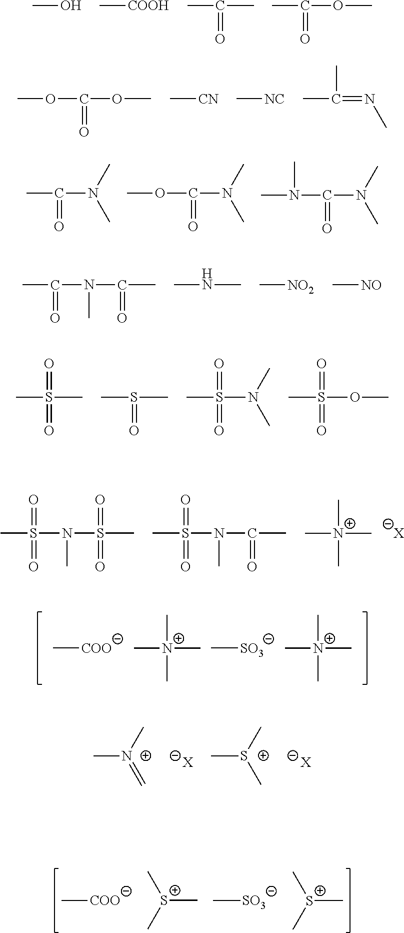

The “polar group” that can be contained in repeating unit (b) is preferably, for example, at least one member selected from the group consisting of (I) a hydroxyl group, (II) a cyano group, (III) a lactone group, (IV) a carboxylic acid group or a sulfonic acid group, (V) an amido group, a sulfonamido group or a group corresponding to a derivative thereof, (VI) an ammonium group or a sulfonium group, and a group comprised of a combination of two or more of these.

This polar group is preferably selected from among a hydroxyl group, a cyano group, a lactone group, a carboxylic acid group, a sulfonic acid group, an amido group, a sulfonamido group, an ammonium group, a sulfonium group and a group comprised of a combination of two or more of these. This polar group is most preferably an alcoholic hydroxyl group, a cyano group, a lactone group or a group in which a cyanolactone structure is incorporated.

The exposure latitude (EL) of compositions comprising the resin can be enhanced by causing the resin to further contain a repeating unit containing an alcoholic hydroxyl group.

The sensitivity of compositions comprising the resin can be enhanced by causing the resin to further contain a repeating unit containing a cyano group.

The dissolution contrast to a developer comprising an organic solvent of compositions can be enhanced by causing the resin to further contain a repeating unit containing a lactone group. Also, if so, the dry etching resistance, applicability and adhesion to substrates of compositions comprising the resin can be enhanced.

The dissolution contrast to a developer comprising an organic solvent of compositions can be enhanced by causing the resin to further contain a repeating unit containing a group with a lactone structure containing a cyano group. Also, if so, the sensitivity, dry etching resistance, applicability and adhesion to substrates of compositions comprising the resin can be enhanced. In addition, if so, the functions respectively attributed to the cyano group and the lactone group can be introduced in a single repeating unit, so that the freedom of design of the resin can be expanded.

When the polar group contained in repeating unit (b) is an alcoholic hydroxyl group, it is preferred for repeating unit (b) to be expressed by at least one member selected from the group consisting of general formulae (I-1H) to (I-10H) below. It is more preferred for repeating unit (b) to be expressed by at least one member selected from the group consisting of general formulae (I-1H) to (I-3H) below. Further more preferably, repeating unit (b) is expressed by general formula (I-1H) below.

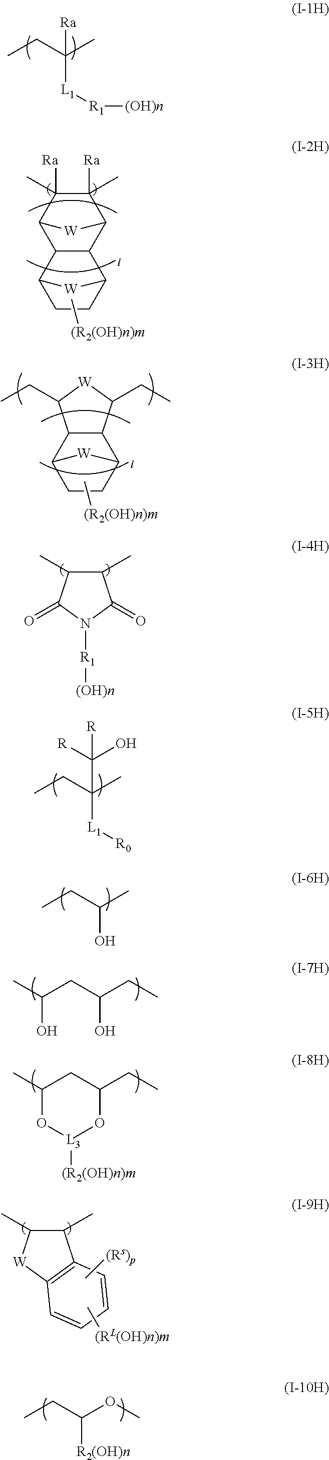

In the formulae, Ra, R₁, R₂, W, n, m, l, L₁, R, R₀, L₃, R^{L}, R^{S} and p are as defined in connection with general formulae (I-1) to (I-10) in section [0233] of JP-A-2011-248019.

When the repeating unit containing a group that is configured to decompose when acted on by an acid to thereby produce an alcoholic hydroxyl group is used in combination with the repeating unit expressed by at least one member selected from the group consisting of general formulae (I-1H) to (I-10H) above, for example, the inhibition of acid diffusion by the alcoholic hydroxyl group coacts with the sensitivity increase by the group that is configured to decompose when acted on by an acid to thereby produce an alcoholic hydroxyl group, thereby realizing an enhancement of exposure latitude (EL) without deterioration of other performances.

The content of repeating unit containing an alcoholic hydroxyl group based on all the repeating units of resin (A) is preferably in the range of 1 to 60 mol %, more preferably 3 to 50 mol % and further more preferably 5 to 40 mol %.

Specific examples of the repeating units expressed by any of general formulae (I-1H) to (I-10H) are shown below. In the specific examples, Ra is as defined above in connection with general formulae (I-1H) to (I-10H).

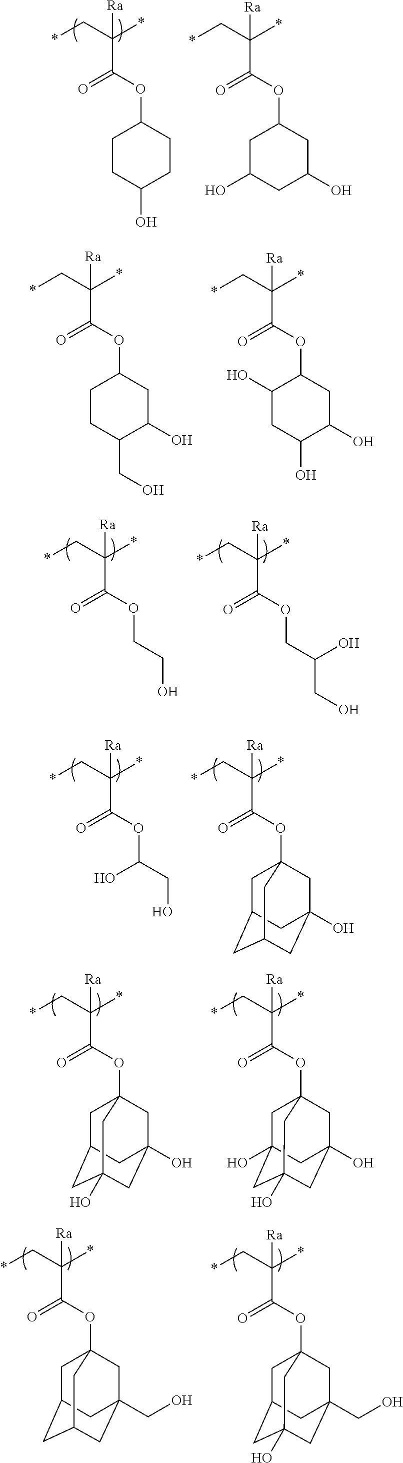

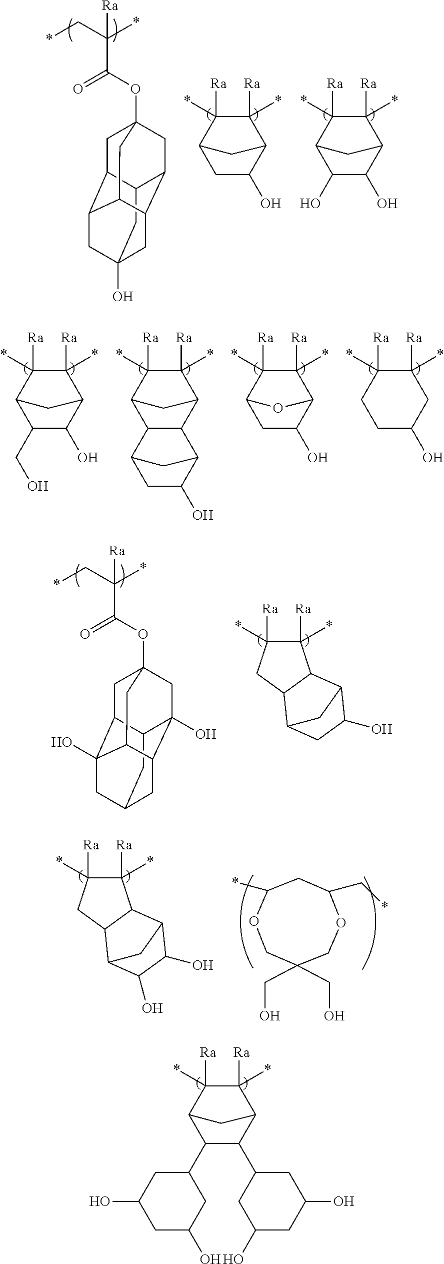

When the polar group contained in repeating unit (b) is an alcoholic hydroxyl group or a cyano group, as a preferred form of the repeating unit, there can be mentioned a repeating unit having an alicyclic hydrocarbon structure substituted with a hydroxyl group or a cyano group. This repeating unit preferably contains no acid-decomposable group. In the alicyclic hydrocarbon structure substituted with a hydroxyl group or a cyano group, the alicyclic hydrocarbon structure is preferably comprised of an adamantyl group, a diamantyl group or a norbornane group. The alicyclic hydrocarbon structure substituted with a hydroxyl group or a cyano group is preferably any of the partial structures of general formulae (VIIa) to (VIIc) below. This structure enhances the adhesion to substrates and developer affinity.

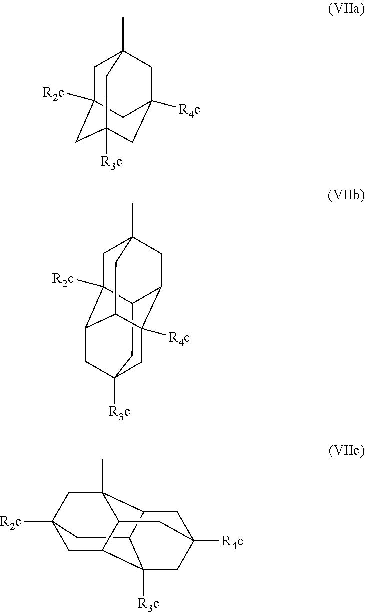

In general formulae (VIIa) to (VIIc),

each of R₂c to R₄c independently represents a hydrogen atom, a hydroxyl group or a cyano group, provided that at least one of R₂c to R₄c represents a hydroxyl group. Preferably, one or two of R₂c to R₄c are hydroxyl groups and the remainder is a hydrogen atom. In general formula (VIIa), more preferably, two of R₂c to R₄c are hydroxyl groups and the remainder is a hydrogen atom.

As the repeating units with partial structures of general formulae (VIIa) to (VIIc), there can be mentioned the repeating units of general formulae (AIIa) to (AIIc) below.

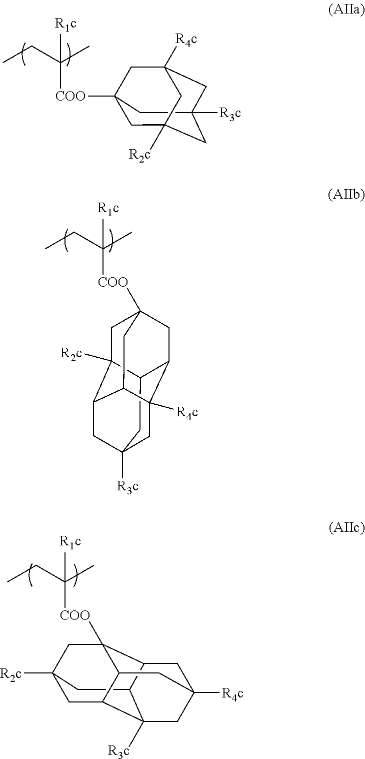

In general formulae (AIIa) to (AIIc),

R₁c represents a hydrogen atom, a methyl group, a trifluoromethyl group or a hydroxymethyl group.

R₂c to R₄c have the same meanings as those of R₂c to R₄c in general formulae (VIIa) to (VIIc).

It is optional for resin (A) to contain the repeating unit containing a hydroxyl group or a cyano group. When the repeating unit is contained, the content of repeating unit containing a hydroxyl group or a cyano group, based on all the repeating units of resin (A), is preferably in the range of 1 to 60 mol %, more preferably 3 to 50 mol % and further more preferably 5 to 40 mol %.

Specific examples of the repeating units each containing a hydroxyl group or a cyano group are shown below, which in no way limit the present invention.

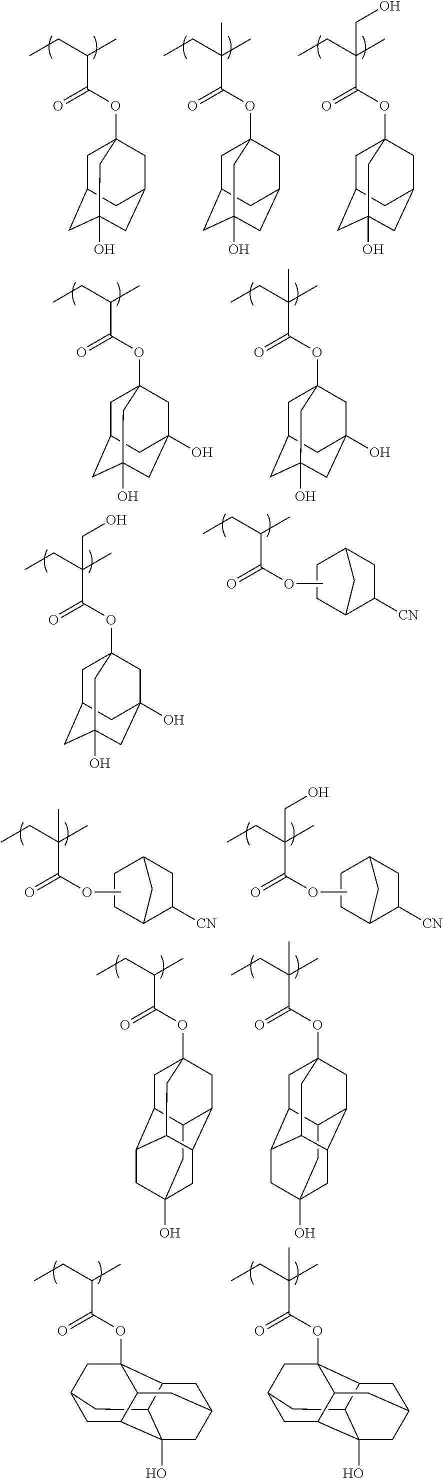

Repeating unit (b) may be a repeating unit containing a lactone structure as the polar group.

It is preferred for the repeating unit containing a lactone structure to be any of repeating units of general formula (AII) below.

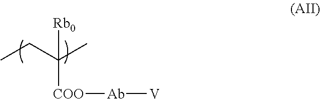

In general formula (AII),

Rb₀ represents a hydrogen atom, a halogen atom or an optionally substituted alkyl group (preferably having 1 to 4 carbon atoms).

Preferred substituents introducible in the alkyl group represented by Rb₀ include a hydroxyl group and a halogen atom. The halogen atom represented by Rb₀ can be a fluorine atom, a chlorine atom, a bromine atom or an iodine atom. Rb₀ is preferably a hydrogen atom, a methyl group, a hydroxymethyl group or a trifluoromethyl group, most preferably a hydrogen atom or a methyl group.

Ab represents a single bond, an alkylene group, a bivalent connecting group with a mono- or polycycloalkyl structure, an ether bond, an ester bond, a carbonyl group, or a bivalent connecting group resulting from a combination of these. Ab is preferably a single bond or any of bivalent connecting groups of the formula -Ab₁-CO₂—.

Ab₁ represents a linear or branched alkylene group or a mono- or polycycloalkylene group, preferably a methylene group, an ethylene group, a cyclohexylene group, an adamantylene group or a norbornylene group.

V represents a group with a lactone structure.

The group with a lactone structure is not limited as long as a lactone structure is contained therein. However, lactone structures of 5 to 7-membered ring are preferred, and in particular, those resulting from condensation of lactone structures of 5 to 7-membered ring with other cyclic structures effected in a fashion to form a bicyclo structure or spiro structure are preferred. The incorporation of a repeating unit containing a lactone structure expressed by any of the following general formulae (LC1-1) to (LC1-17) is more preferred. The lactone structures may be directly bonded to the principal chain. Preferred lactone structures are those of formulae (LC1-1), (LC1-4), (LC1-5), (LC1-6), (LC1-8), (LC1-13) and (LC1-14).

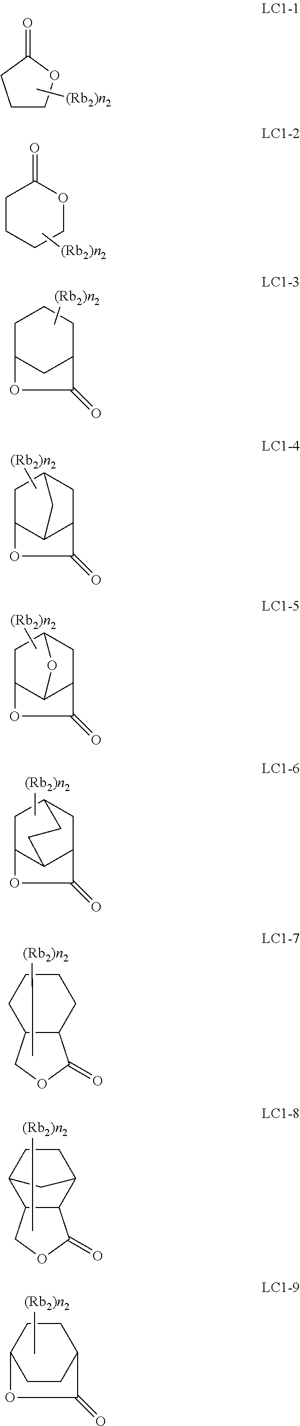

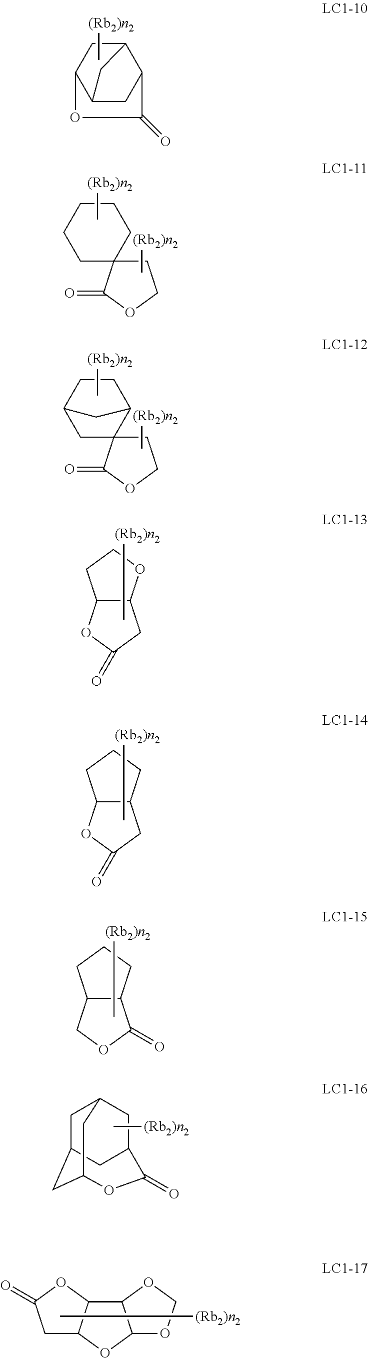

It is optional to introduce a substituent (Rb₂) in each portion of lactone structure. As a preferred substituent (Rb₂), there can be mentioned an alkyl group having 1 to 8 carbon atoms, a monocycloalkyl group having 4 to 7 carbon atoms, an alkoxy group having 1 to 8 carbon atoms, an alkoxycarbonyl group having 2 to 8 carbon atoms, a carboxyl group, a halogen atom, a hydroxyl group, a cyano group, an acid-decomposable group or the like. Of these, an alkyl group having 1 to 4 carbon atoms, a cyano group and an acid-decomposable group are more preferred. In the formulae, n₂ is an integer of 0 to 4. When n₂ is 2 or greater, the plurally present substituents (Rb₂) may be identical to or different from each other. Further, the plurally present substituents (Rb₂) may be bonded to each other to thereby form a ring.

The repeating unit containing a lactone group is generally present in the form of optical isomers. Any optical isomer may be used. It is both appropriate to use a single type of optical isomer alone or a plurality of optical isomers in the form of a mixture. When a single type of optical isomer is mainly used, the optical purity (ee) thereof is preferably 90% or higher, more preferably 95% or higher.

It is optional for resin (A) to contain a repeating unit with a lactone structure. When the repeating unit with a lactone structure is contained, the content of this repeating unit in resin (A), based on all the repeating units, is preferably in the range of 1 to 70 mol %, more preferably 3 to 65 mol % and further more preferably 5 to 60 mol %.

Particular examples of the repeating units with a lactone structure in resin (A) are shown below, which in no way limit the present invention. In the formulae, Rx represents H, CH₃, CH₂OH or CF₃.

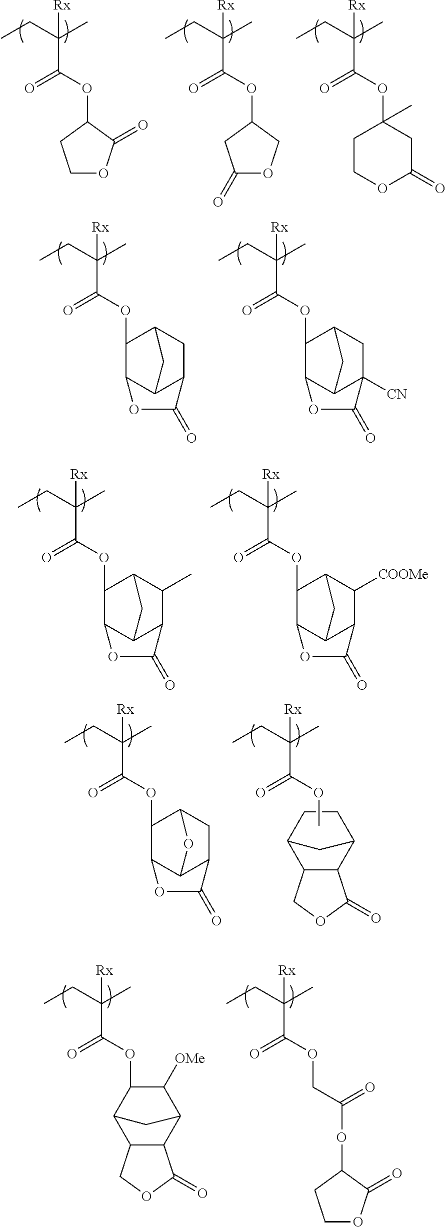

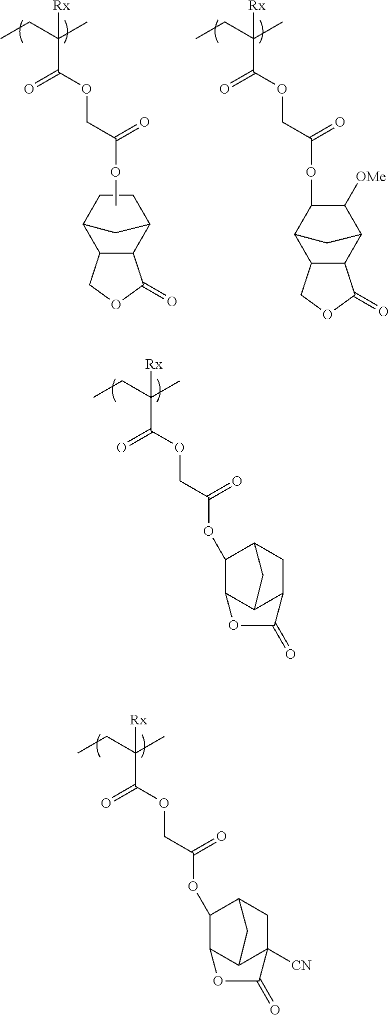

That the polar group introduced in repeating unit (b) is an acid group also provides an especially preferred form of the repeating unit. Namely, it is preferred for resin (A) to contain a repeating unit containing an acid group. Preferred acid groups include a phenolic hydroxyl group, a carboxylic acid group, a sulfonic acid group, a fluoroalcohol group (e.g., a hexafluoroisopropanol group), a sulfonamido group, a sulfonylimido group, an (alkylsulfonyl)(alkylcarbonyl)methylene group, an (alkylsulfonyl)(alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group and a tris(alkylsulfonyl)methylene group. It is especially preferred for repeating unit (b) to be a repeating unit containing a carboxyl group. The incorporation of the repeating unit containing an acid group enhances the resolution in contact hole usage. The repeating unit containing an acid group is preferably any of a repeating unit wherein the acid group is directly bonded to the principal chain of a resin such as a repeating unit of acrylic acid or methacrylic acid, a repeating unit wherein the acid group is bonded via a connecting group to the principal chain of a resin and a repeating unit wherein the acid group is introduced in a terminal of a polymer chain by the use of a chain transfer agent or polymerization initiator containing the acid group in the stage of polymerization. The repeating unit of acrylic acid or methacrylic acid is especially preferred.

It is optional for the acid group introducible in repeating unit (b) to contain an aromatic ring. When an aromatic ring is contained, the acid group is preferably selected from among acid groups other than a phenolic hydroxyl group. When repeating unit (b) contains an acid group, the content of repeating unit containing an acid group, based on all the repeating units of resin (A), is preferably 30 mol % or less, more preferably 20 mol % or less. When resin (A) contains a repeating unit containing an acid group, the content of repeating unit containing an acid group in resin (A) is generally 1 mol % or greater.

Particular examples of the repeating units each containing an acid group are shown below, which in no way limit the present invention. In the particular examples, Rx represents H, CH₃, CH₂OH or CF₃.

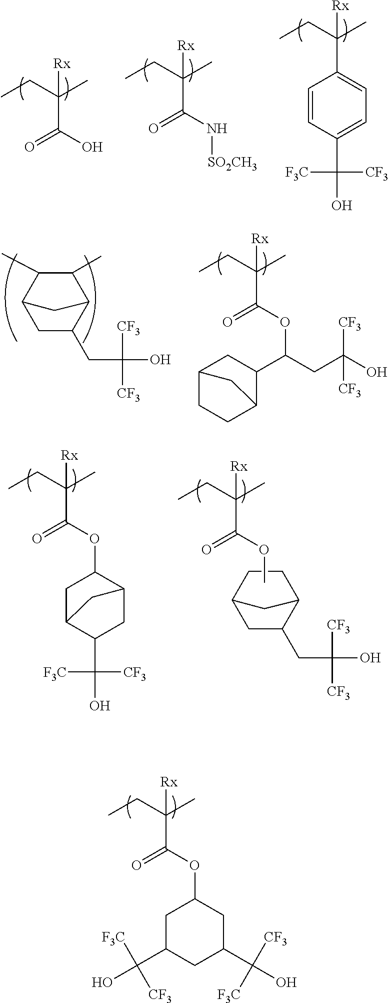

Resin (A) according to the present invention may contain non-acid-decomposable repeating unit (b) containing a phenolic hydroxyl group. It is preferred for this repeating unit (b) to have any of structures of general formula (I) below.

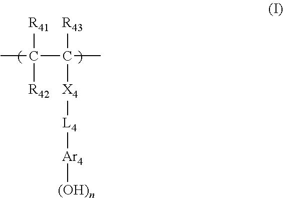

In the formula,

each of R₄₁, R₄₂ and R₄₃ independently represents a hydrogen atom, an alkyl group, a halogen atom, a cyano group or an alkoxycarbonyl group, provided that R₄₂ may be bonded to Ar₄ to thereby form a ring, which R₄₂ in that instance is a single bond or an alkylene group.

X₄ represents a single bond, —COO— or —CONR₆₄— in which R₆₄ represents a hydrogen atom or an alkyl group.

L₄ represents a single bond or an alkylene group.

Ar₄ represents a (n+1)-valent aromatic ring group, provided that when Ar₄ is bonded to R₄₂ to thereby form a ring, which Ar₄ is a (n+2)-valent aromatic ring group, and

n is an integer of 1 to 4.

Ar₄ represents a (n+1)-valent aromatic ring group. A substituent may be introduced in the bivalent aromatic ring group in which n is 1. As preferred examples thereof, there can be mentioned an arylene group having 6 to 18 carbon atoms, such as a phenylene group, a tolylene group, a naphthylene group or an anthracenylene group, and an aromatic ring group containing a heteroring, such as thiophene, furan, pyrrole, benzothiophene, benzofuran, benzopyrrole, triazine, imidazole, benzimidazole, triazole, thiadiazole or thiazole.

As preferred particular examples of the (n+1)-valent aromatic ring groups in which n is an integer of 2 or greater, there can be mentioned groups resulting from the removal of (n−1) arbitrary hydrogen atoms from each of the above-mentioned particular examples of bivalent aromatic ring groups.

Further substituents may be introduced in the (n+1)-valent aromatic ring groups.

Substituents that can be introduced in the above-mentioned alkyl group, alkoxycarbonyl group, alkylene group and (n+1)-valent aromatic ring group include an alkyl group, an alkoxy group, such as a methoxy group, an ethoxy group, a hydroxyethoxy group, a propoxy group, a hydroxypropoxy group or a butoxy group, and an aryl group, such as a phenyl group.

X₄ is preferably a single bond, —COO— or —CONH—, more preferably a single bond or —COO—.

The alkylene group represented by L₄ is preferably an optionally substituted alkylene group having 1 to 8 carbon atoms, such as a methylene group, an ethylene group, a propylene group, a butylene group, a hexylene group or an octylene group.

Ar₄ is more preferably an optionally substituted aromatic ring group having 6 to 18 carbon atoms. A benzene ring group, a naphthalene ring group and a biphenylene ring group are most preferred.

It is preferred for repeating unit (b) to contain a hydroxystyrene structure. Namely, it is preferred for Ar₄ to be a benzene ring group.

Particular examples of repeating units (b) expressed by general formula (I) are shown below, which in no way limit the present invention. In the formulae, a is 1 or 2.

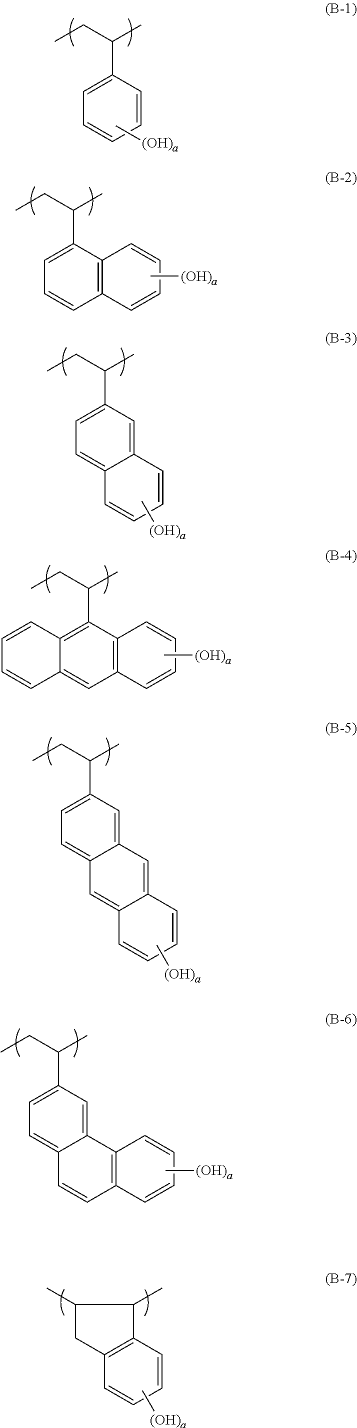

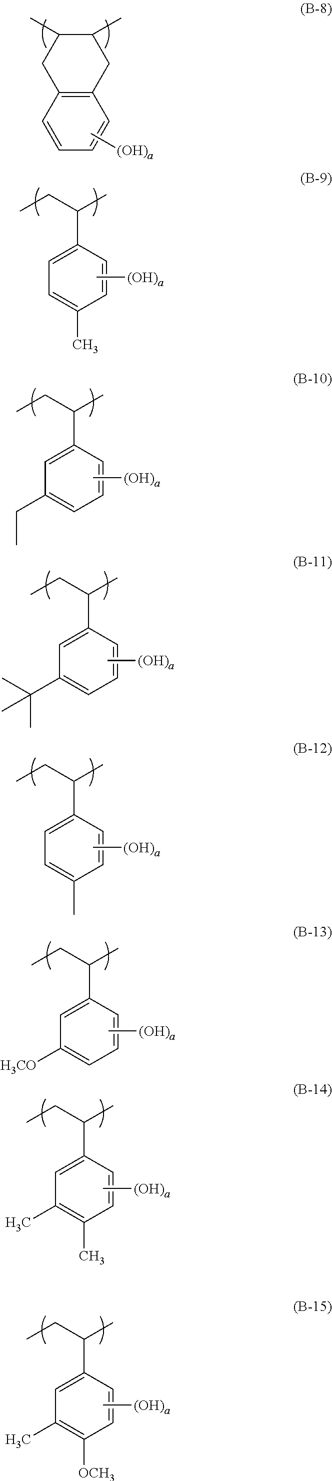

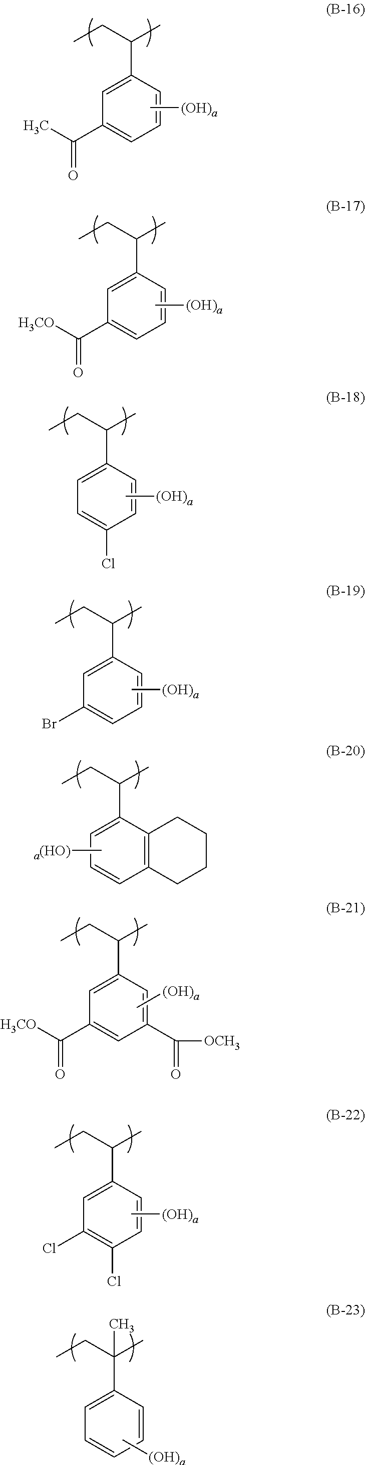

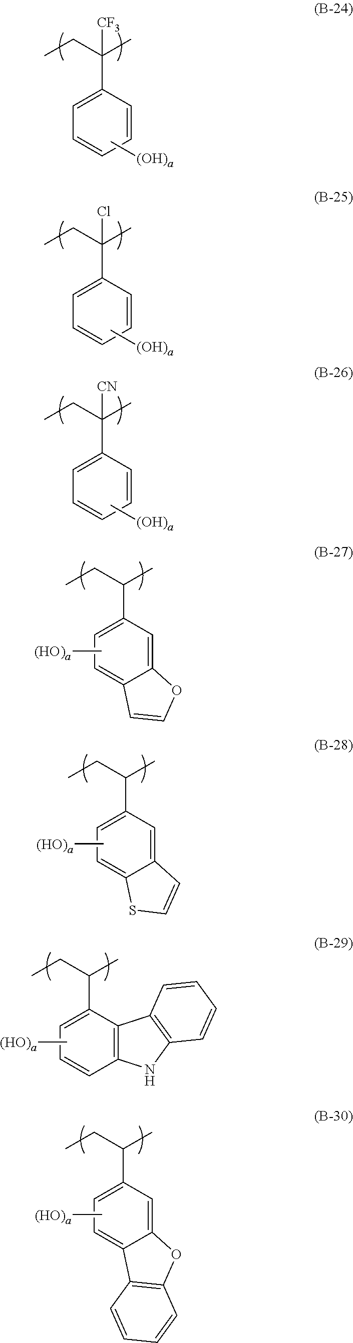

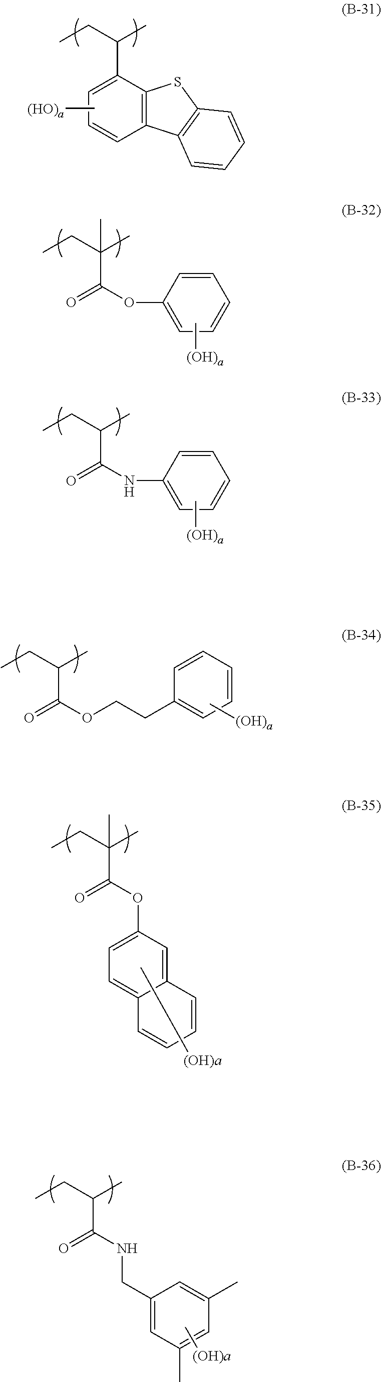

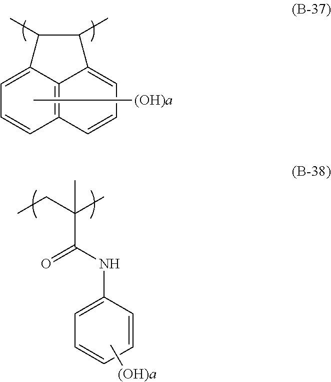

Resin (A) may contain two or more of the repeating units of general formula (I).

The repeating unit containing a phenolic hydroxyl group, like repeating unit (b) expressed by general formula (I), tends to increase the solubility of resin (A) in an organic solvent, so that there are occasions in which avoiding much addition thereof is preferred from the viewpoint of resolution. This tendency is magnificent with respect to the repeating units derived from hydroxystyrenes (namely, those of general formula (I) in which both X₄ and L₄ are single bonds). The reason therefor has not been elucidated. However, it can be presumed that a possible cause thereof is, for example, the presence of a phenolic hydroxyl group in the vicinity of the principal chain. Therefore, in the present invention, the content of repeating unit expressed by general formula (I) (preferably, any of repeating units of general formula (I) in which both X₄ and L₄ are single bonds), based on all the repeating units of resin (A), is preferably 4 mol % or less, more preferably 2 mol % or less and most preferably 0 mol % (namely, none contained).

(c) Repeating Unit Containing a Plurality of Aromatic Rings

Resin (A) may contain a repeating unit (c) containing a plurality of aromatic rings expressed by general formula (c1) below.

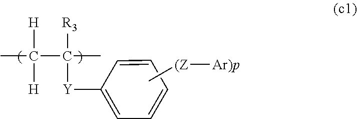

In general formula (c1),

R₃ represents a hydrogen atom, an alkyl group, a halogen atom, a cyano group or a nitro group;

Y represents a single bond or a bivalent connecting group;

Z represents a single bond or a bivalent connecting group;

Ar represents an aromatic ring group; and

p is an integer of 1 or greater.

Repeating unit (c) is more preferably any of repeating units of general formula (c2) below.

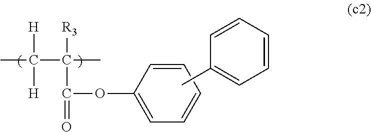

In general formula (c2), R₃ represents a hydrogen atom or an alkyl group.

With respect to the exposure to extreme ultraviolet (EUV light), any leak light (out-of-band light) occurring in the ultraviolet region of wavelength 100 to 400 nm deteriorates the surface roughness, so that the resolution and LWR performance tend to deteriorate through inter-pattern bridge and pattern breaking.

However, the aromatic rings in repeating unit (c) function as an interior filter capable of absorbing the above out-of-band light. Therefore, from the viewpoint of high resolution and low LWR, it is preferred for resin (A) to contain repeating unit (c).

In this connection, it is preferred for repeating unit (c) to contain no phenolic hydroxyl group (hydroxyl group directly bonded onto an aromatic ring) from the viewpoint of realizing high resolution.

Nonlimiting particular examples of repeating units (c) are shown below.

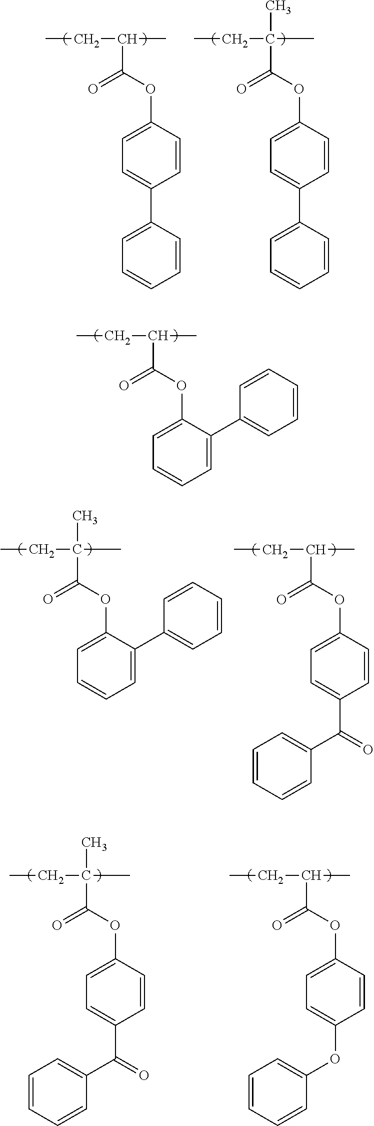

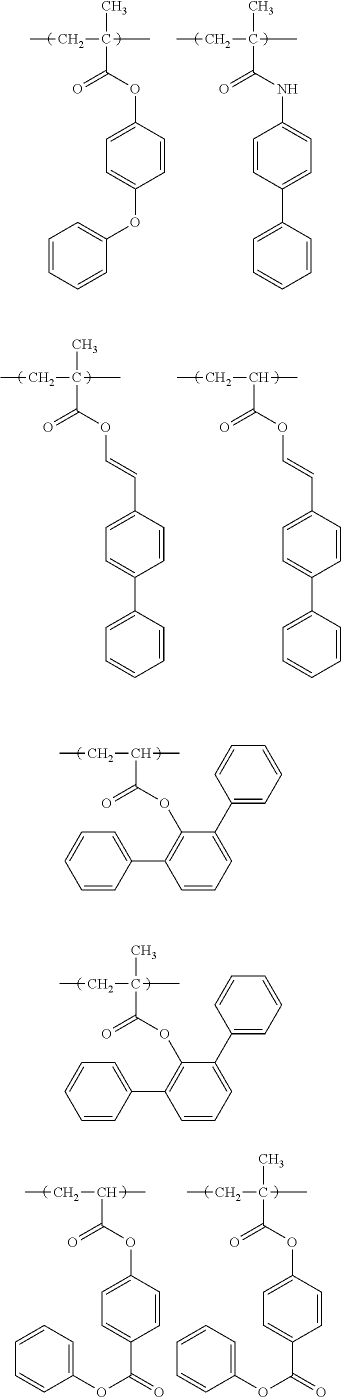

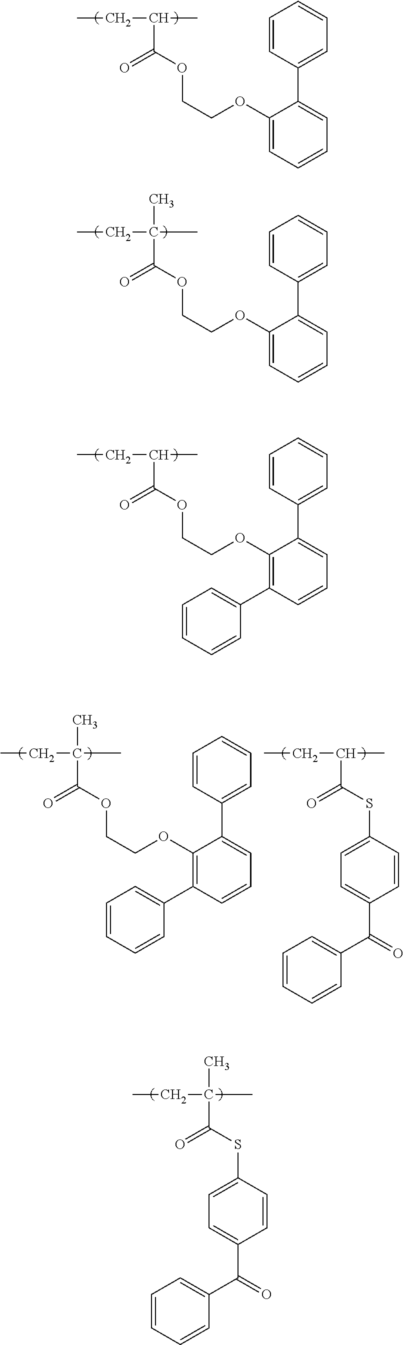

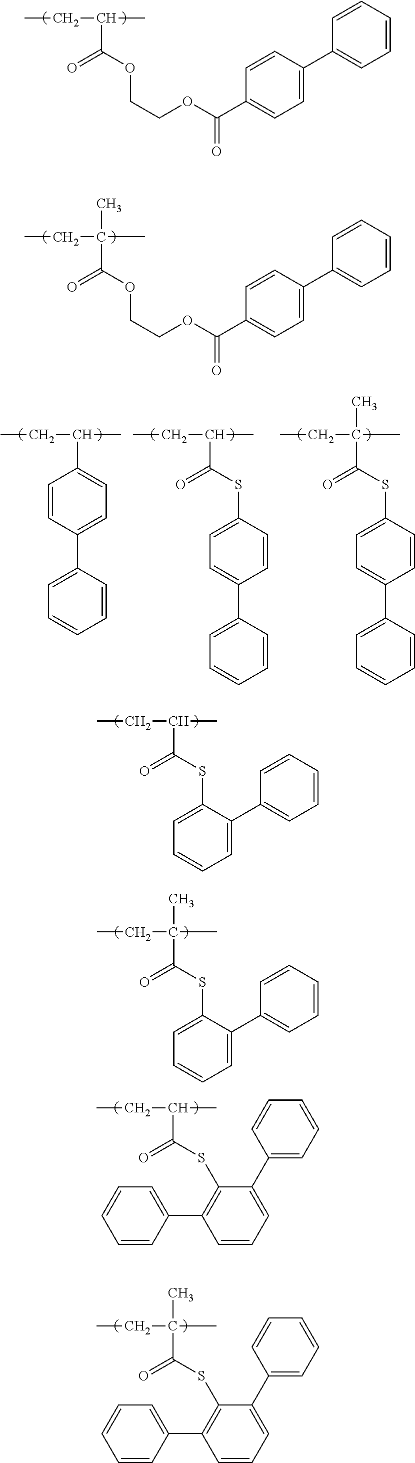

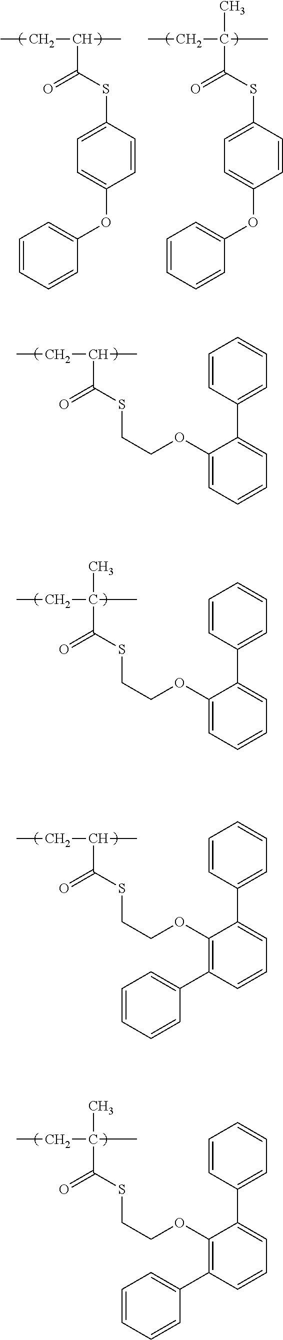

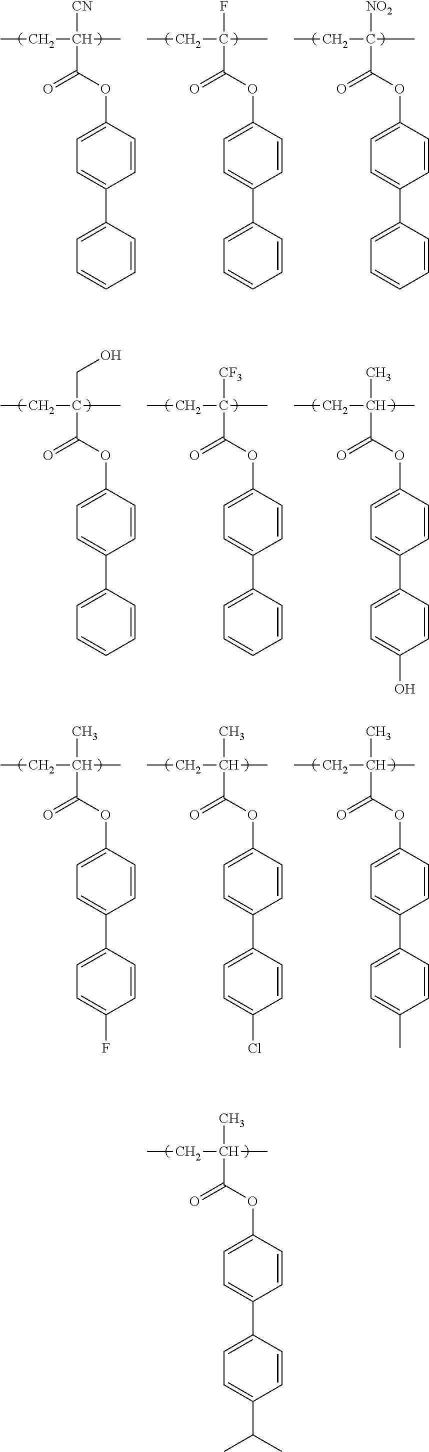

It is optional for resin (A) to contain repeating unit (c). When repeating unit (c) is contained, the content thereof based on all the repeating units of resin (A) is preferably in the range of 1 to 30 mol %, more preferably 1 to 20 mol % and further more preferably 1 to 15 mol %. Two or more repeating units (c) may be contained in combination in resin (A).

Resin (A) according to the present invention may further appropriately contain repeating units other than the foregoing repeating units (a) to (c). Resin (A) can further contain, as an example of such other repeating units, a repeating unit having an alicyclic hydrocarbon structure in which no polar group (for example, the above acid group, hydroxyl group or cyano group) is introduced and exhibiting no acid-decomposability. This realizes an appropriate regulation of the solubility of the resin in the stage of development. As such a repeating unit, there can be mentioned any of the repeating units of general formula (IV) described in section [0331] of JP-A-2011-248019. The definition and specific examples of groups in general formula (IV) are as set forth in sections [0332] to [0339] of JP-A-2011-248019.

It is optional for resin (A) to contain a repeating unit having an alicyclic hydrocarbon structure in which no polar group is introduced and exhibiting no acid-decomposability. When this repeating unit is contained, the content thereof based on all the repeating units of resin (A) is preferably in the range of 1 to 20 mol %, more preferably 5 to 15 mol %.

The following monomer components may be introduced in resin (A) in view of increases of Tg and dry etching resistance as well as the above-mentioned effect of interior filter for out-of-band light or the like.

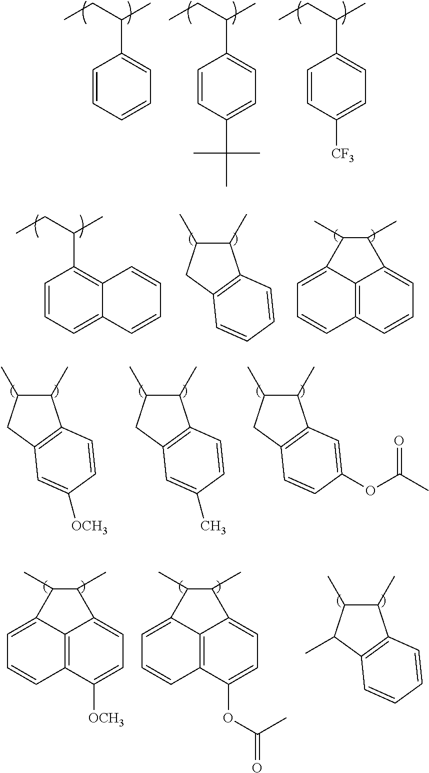

In resin (A) for use in the composition of the present invention, the molar ratios of individual repeating structural units contained are appropriately determined from the viewpoint of regulating the dry etching resistance, standard developer adaptability, substrate adhesion and resist profile of the resist and generally required properties of the resist such as resolving power, heat resistance and sensitivity.

Resin (A) according to the present invention may have any of the random, block, comb and star forms. Resin (A) can be synthesized through the process described in sections [0172] to [0183] of JP-A-2012-208447.

The molecular weight of resin (A) according to the present invention is not particularly limited. Preferably, the weight average molecular weight thereof is in the range of 1000 to 100,000. It is more preferably in the range of 1500 to 60,000, most preferably 2000 to 30,000. By regulating the weight average molecular weight so as to fall within the range of 1000 to 100,000, not only can any deteriorations of heat resistance and dry etching resistance be prevented but also any deterioration of developability and any increase of viscosity leading to poor film forming property can be prevented. Herein, the weight average molecular weight of the resin refers to the polystyrene-equivalent molecular weight measured by GPC (carrier: THF or N-methyl-2-pyrrolidone (NMP)).

The polydispersity index (Mw/Mn) of the resin is preferably in the range of 1.00 to 5.00, more preferably 1.03 to 3.50 and further more preferably 1.05 to 2.50. The narrower the molecular weight distribution, the more favorable the resolution and resist shape and also the smoother the side wall of the resist pattern to thereby attain an excellence in roughness characteristics.

One of these reins (A) according to the present invention may be used alone, or two or more thereof may be used in combination. The content of resin (A) is preferably in the range of 20 to 99 mass %, more preferably 30 to 89 mass % and most preferably 40 to 79 mass %, based on the total solids of the electron-beam- or extreme-ultraviolet-sensitive resin composition of the present invention.

[2] Compound (B) that is Configured to Produce an Acid when Exposed to Actinic Rays or Radiation

The composition of the present invention comprises a compound (hereinafter also referred to as “acid generator”) that is configured to produce an acid when exposed to actinic rays or radiation. The acid generator contained in the composition of the present invention is preferably a compound that is configured to produce an acid when exposed to electron beams or extreme ultraviolet. The acid produced by the acid generator contained in the composition of the present invention exhibits a Log P value of 3.0 or below and has a molecular weight (hereinafter also referred to as Mw) of 430 or greater.

Herein, the Log P value refers to the logarithm of n-octanol/water partition coefficient (P), which is an effective parameter capable of characterizing the hydrophilicity/hydrophobicity with respect to a vast variety of compounds. The partition coefficient is generally determined by calculation, not by experiment. In the present invention, the values calculated by ChemDrawPro12 are indicated.

The Log P value of the acid produced by the acid generator contained in the composition of the present invention is preferably in the range of −3.0 to 3.0, more preferably −2.5 to 2.0 and most preferably −2.0 to 1.5. It is presumed that the acid diffusion in the stage of post-exposure bake (PEB) is uniformized by using an acid generator capable of producing an acid whose Log P value falls within the above range. This results in the formation of favorable pattern. Further, the acid generator capable of producing an acid whose Log P value falls within the above range can be dissolved in generally employed resist solvents without any difficulty.

The molecular weight of the acid produced by the acid generator contained in the composition of the present invention is preferably in the range of 430 to 1000, more preferably 450 to 900 and most preferably 500 to 800. In the pattern formation, a finer more favorable pattern can be formed when the diffusion of the acid produced by the acid generator is lower, namely, the molecular weight of the produced acid is larger. It is presumed that the reason therefor is that larger molecular weights decrease the diffusion in the stage of post-exposure bake (PEB) to thereby ensure effective maintenance of acid latent images, resulting in high resolution. This effect is magnificent when the exposure is performed to electron beams or extreme ultraviolet. The composition of the present invention excels in the resolution in pattern formation by virtue of the incorporation of the acid generator exhibiting the above Log P value and having the above molecular weight. Moreover, patterns enhanced in line width roughness and top roughness can be formed by using the composition of the present invention.

It is preferred for the acid generator for use in the present invention to be a compound capable of producing an organic acid, for example, at least any one of sulfonic acid, a bis(alkylsulfonyl)imide and a tris(alkylsulfonyl)methide when exposed to actinic rays or radiation.

Among the acid generators contained in the composition of the present invention, especially preferred examples are shown below. In the examples, the Log P value means the Log P value of the acid produced by the acid generator. The Mw value means the molecular weight of the acid produced by the acid generator.

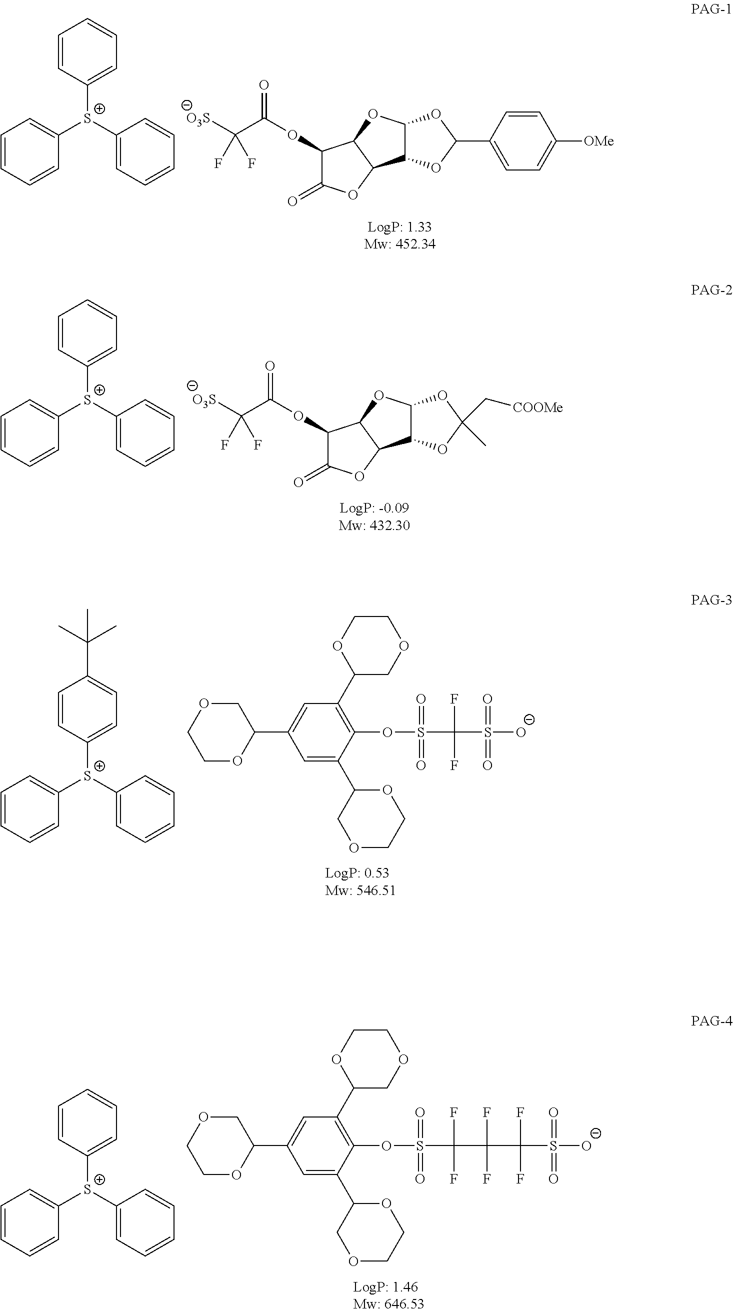

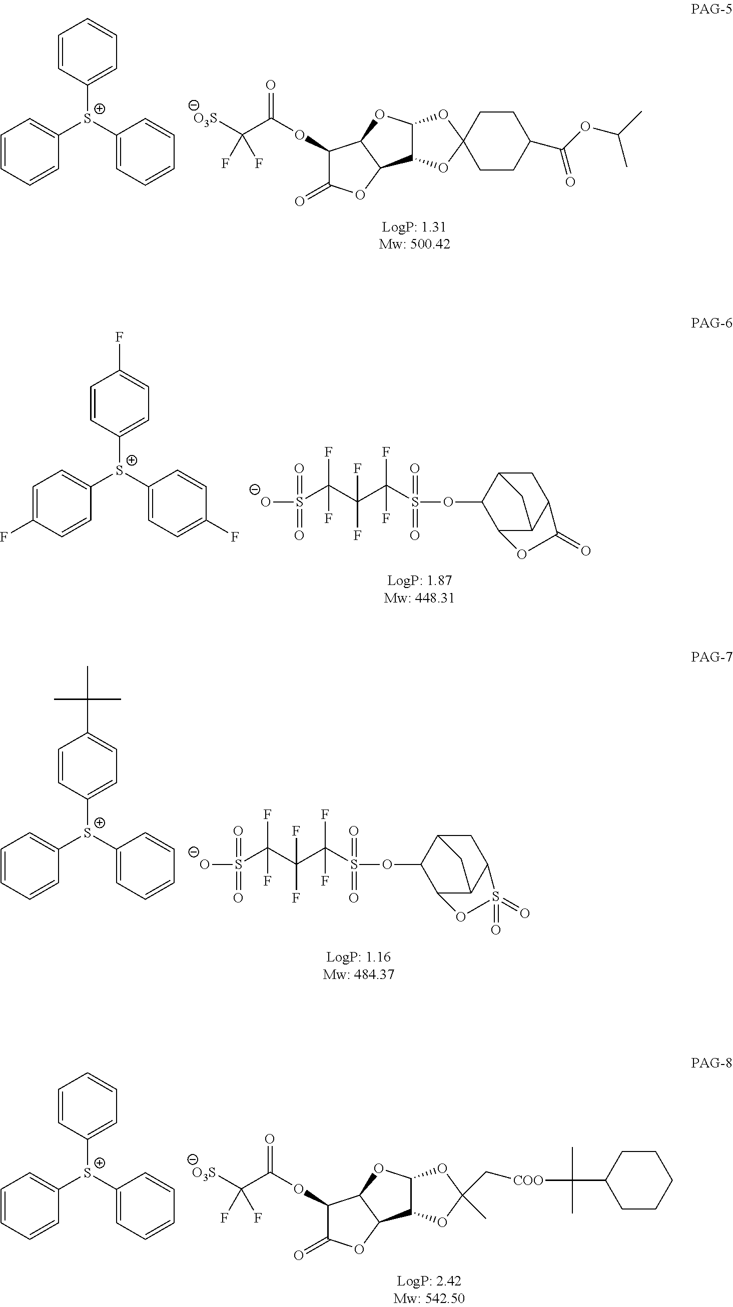

One of the above acid generators may be used alone, or two or more thereof may be used in combination.

The content of acid generator in the composition, based on the total solids of the composition, is preferably in the range of 5 to 70 mass %. The resolution, LWR and top roughness can be effectively enhanced by regulating the content of acid generator so as to fall within the above range.

The content of acid generator in the composition, based on the total solids of the composition, is more preferably in the range of 10 to 70 mass %, further more preferably 20 to 60 mass % and most preferably 30 to 50 mass %.

[3] Solvent

The solvent usable in the preparation of the composition is not particularly limited as long as the individual components can be dissolved. For example, use can be made of an alkylene glycol monoalkyl ether carboxylate (propylene glycol monomethyl ether acetate (PGMEA; also known as 1-methoxy-2-acetoxypropane) or the like), an alkylene glycol monoalkyl ether (propylene glycol monomethyl ether (PGME; 1-methoxy-2-propanol) or the like), an alkyl lactate (ethyl lactate, methyl lactate or the like), a cyclolactone (γ-butyrolactone or the like, preferably having 4 to 10 carbon atoms), a chain or cyclic ketone (2-heptanone, cyclohexanone or the like, preferably having 4 to 10 carbon atoms), an alkylene carbonate (ethylene carbonate, propylene carbonate or the like), an alkyl carboxylate (preferably an alkyl acetate, such as butyl acetate), an alkyl alkoxyacetate (ethyl ethoxypropionate) or the like. As other useful solvents, there can be mentioned, for example, those described in section [0244] et seq. of US Patent Application Publication NO. 2008/0248425 A1 and the like.

Among these solvents, an alkylene glycol monoalkyl ether carboxylate and an alkylene glycol monoalkyl ether are preferred.

Any one of these solvents may be used alone, or two or more thereof may be used in combination. When two or more of solvents are mixed together, it is preferred to mix a hydroxylated solvent with a non-hydroxylated solvent. The mass ratio of hydroxylated solvent to non-hydroxylated solvent is in the range of 1/99 to 99/1, preferably 10/90 to 90/10 and more preferably 20/80 to 60/40.

The hydroxylated solvent is preferably an alkylene glycol monoalkyl ether. The non-hydroxylated solvent is preferably an alkylene glycol monoalkyl ether carboxylate.

[4] Basic Compound

It is preferred for the actinic-ray- or radiation-sensitive resin composition of the present invention to contain a basic compound.

The basic compound is preferably a nitrogen-containing organic basic compound.

Useful compounds are not particularly limited. However, for example, the compounds of categories (1) to (5) below are preferably used.

(1) Compounds of General Formula (BS-1) Below

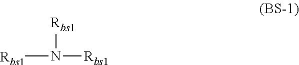

In general formula (BS-1),

each of R_{bs1}s independently represents any of a hydrogen atom, an alkyl group (linear or branched), a cycloalkyl group (mono- or polycyclic), an aryl group and an aralkyl group, provided that in no event all three R_{bs1}s are hydrogen atoms.

The basic compounds of general formula (BS-1) include, for example, the following.

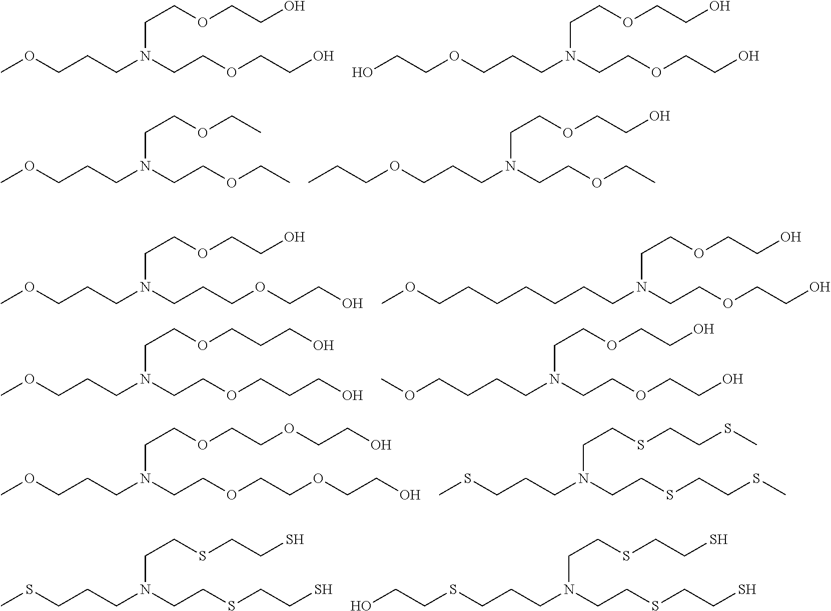

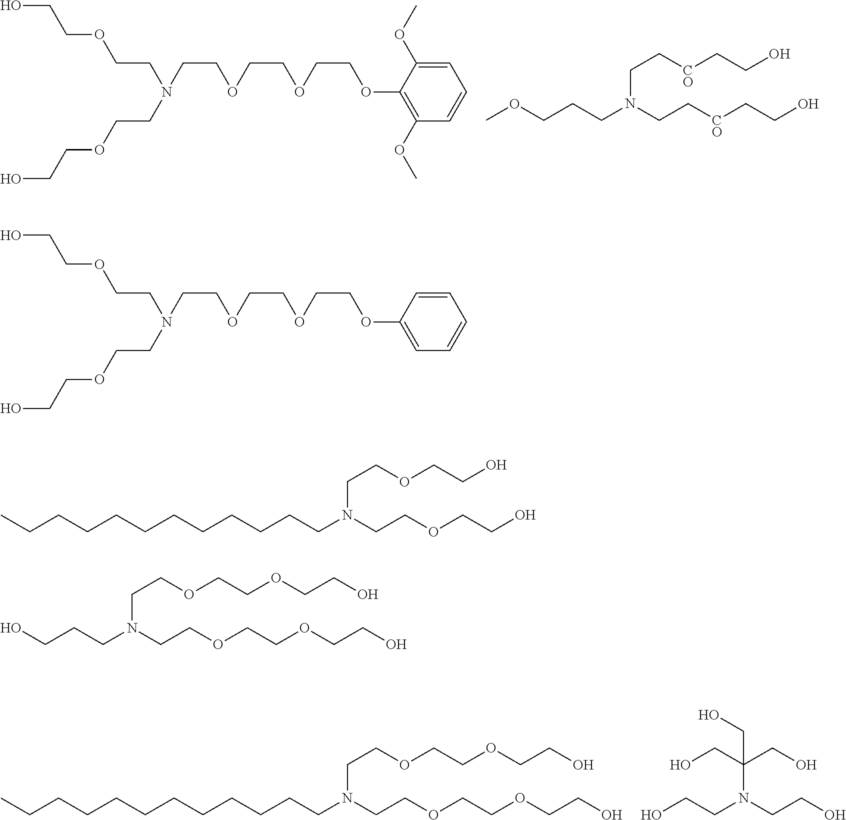

(2) Compound with Nitrogen-Containing Heterocyclic Structure

The heterocyclic structure may be aromatic or nonaromatic. The heterocyclic structure may contain a plurality of nitrogen atoms, and also may contain a heteroatom other than nitrogen. For example, there can be mentioned compounds with an imidazole structure (2-phenylbenzimidazole, 2,4,5-triphenylimidazole and the like), compounds with a piperidine structure (N-hydroxyethylpiperidine, bis(1,2,2,6,6-pentamethyl-4-piperidyl) sebacate and the like), compounds with a pyridine structure (4-dimethylaminopyridine and the like) and compounds with an antipyrine structure (antipyrine, hydroxyantipyrine and the like).

Further, compounds with two or more ring structures can also be appropriately used. In particular, there can be mentioned, for example, 1,5-diazabicyclo[4.3.0]non-5-ene and 1,8-diazabicyclo[5.4.0]-undec-7-ene.

(3) Amine Compound Containing Phenoxy Group

The amine compound containing a phenoxy group refers to one containing a phenoxy group at the end of the alkyl group of the amine compound opposite to the nitrogen atom. A substituent may be introduced in the phenoxy group. The substituent is, for example, an alkyl group, an alkoxy group, a halogen atom, a cyano group, a nitro group, a carboxyl group, a carboxylic ester group, a sulfonic ester group, an aryl group, an aralkyl group, an acyloxy group or an aryloxy group.

More preferably, the amine compound containing a phenoxy group is a compound containing at least one alkyleneoxy chain between the phenoxy group and the nitrogen atom. The number of alkyleneoxy chains in each molecule is preferably in the range of 3 to 9, more preferably 4 to 6. Among the alkyleneoxy chains, —CH₂CH₂O— is preferred.

Particular examples thereof include 2-[2-{2-(2,2-dimethoxy-phenoxyethoxy)ethyl}-bis(2-methoxyethyl)]-amine and compounds (C1-1) to (C3-3) shown by way of example in section [0066] of US Patent Application Publication No. 2007/0224539 A1.

(4) Ammonium Salt

Ammonium salts can also be appropriately used. Ammonium hydroxides and carboxylates are preferred. Particular preferred examples thereof are tetraalkylammonium hydroxides whose representative is tetrabutylammonium hydroxide. Aside from these, use can be made of ammonium salts derived from the above amines (1) to (3).

(5) Guanidine Compound

The composition of the present invention may further comprise a guanidine compound.

Nonlimiting particular examples of the guanidine compounds are shown below.

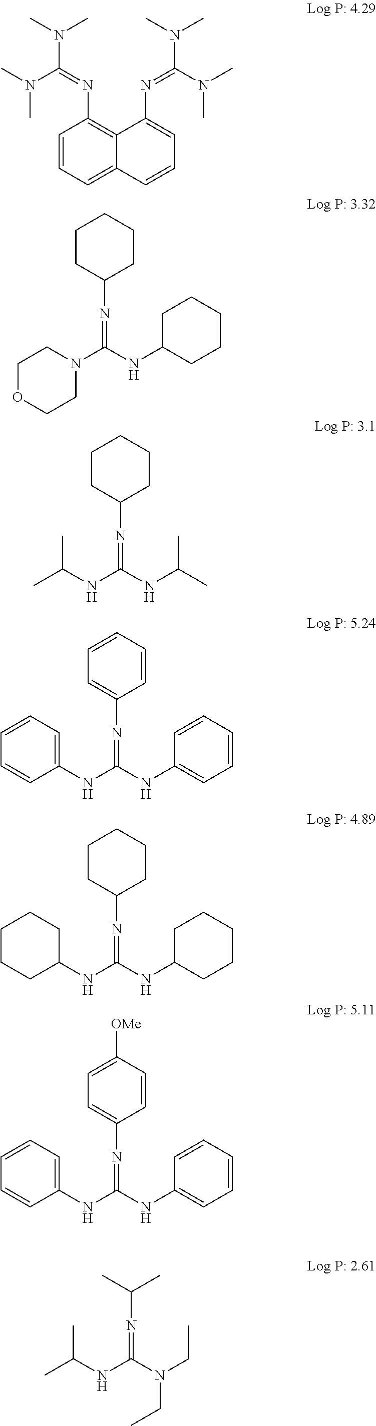

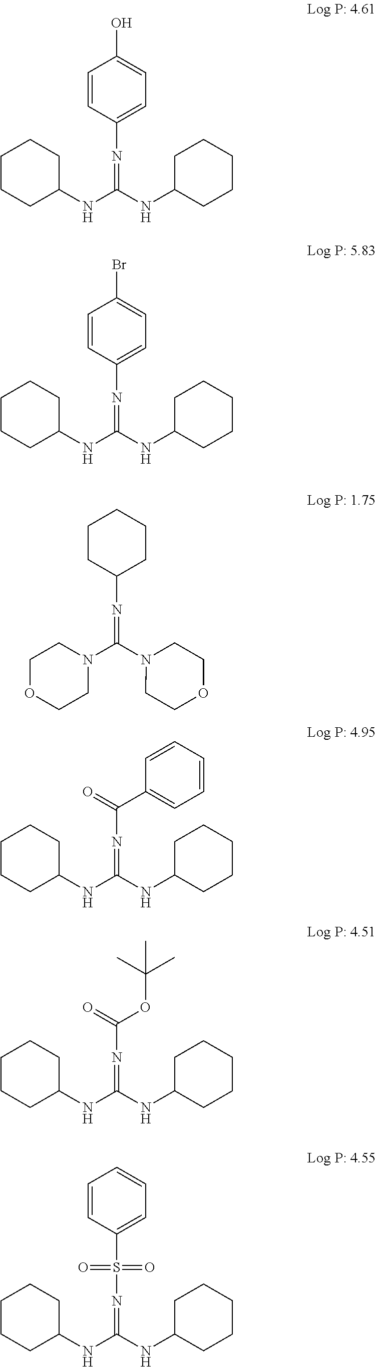

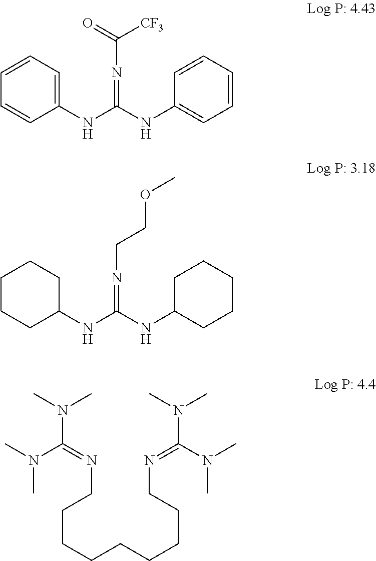

As other usable basic compounds, there can be mentioned compounds set forth in JP-A-2011-85926, compounds synthesized in Examples of JP-A-2002-363146, compounds described in section [0108] of JP-A-2007-298569 and the like.

The composition of the present invention may contain, as a basic compound, a low-molecular compound (hereinafter also referred to as “low-molecular compound (D)” or “compound (D)”) containing a nitrogen atom and containing a group leaving under the action of an acid.

Particular examples of compounds (D) especially preferred in the present invention are shown below, which in no way limit the present invention.

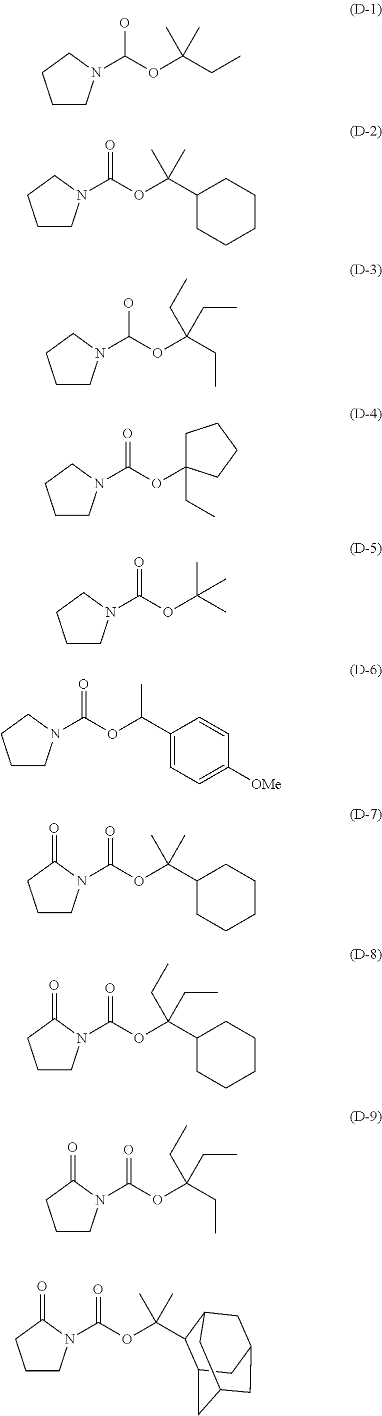

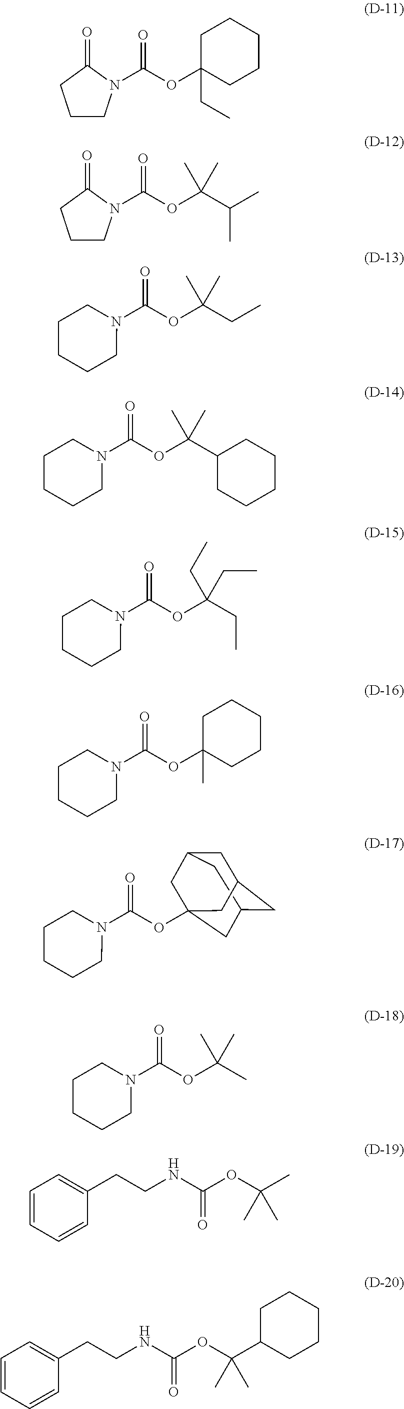

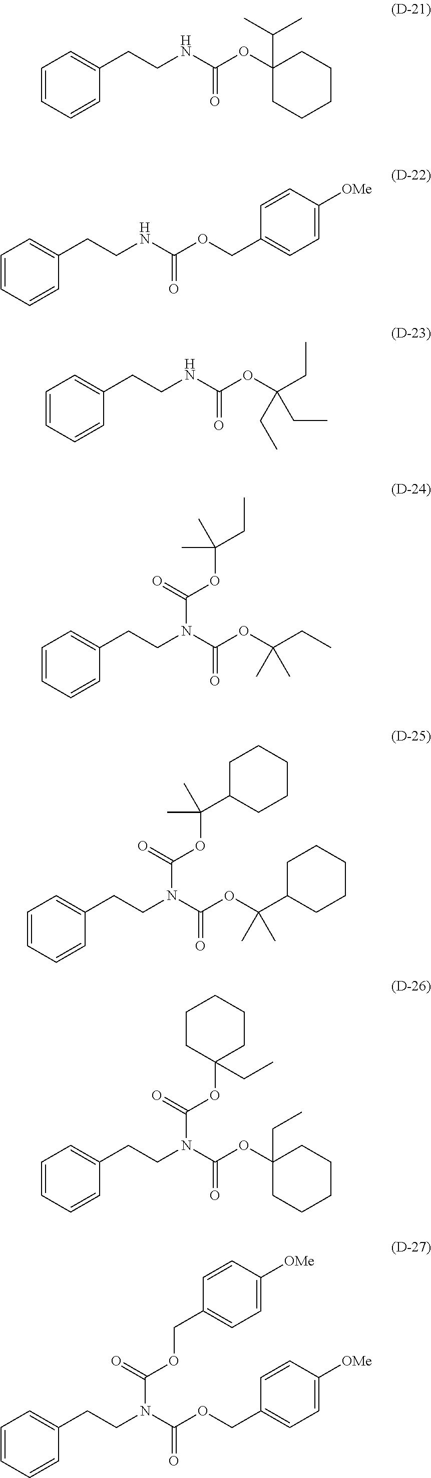

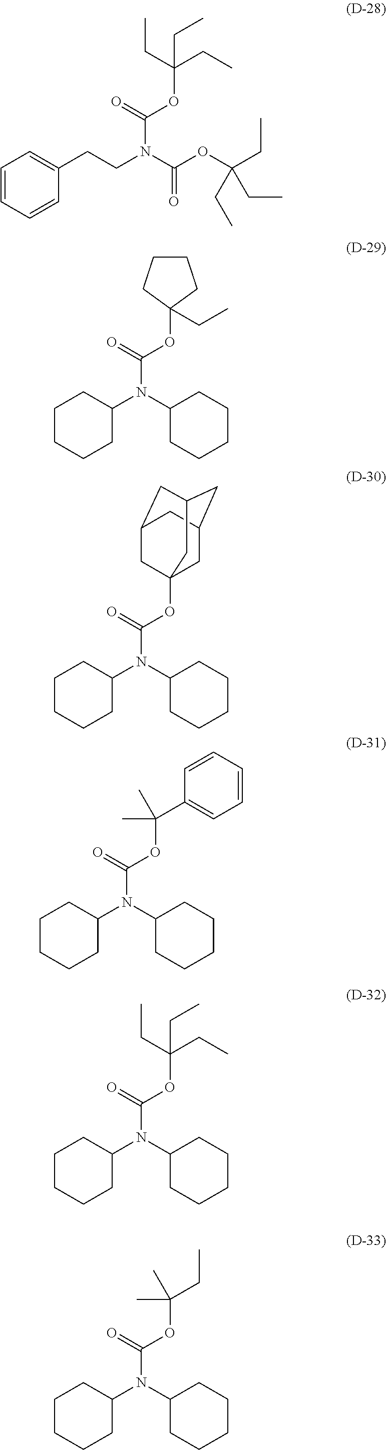

Furthermore, appropriate use can be made of a photolytic basic compound (compound that initially exhibits basicity since a basic nitrogen atom acts as a base but when exposed to actinic rays or radiation, is decomposed to thereby generate an amphoteric ion compound containing a basic nitrogen atom and an organic acid moiety, these inducing an intramolecular neutralization to thereby result in decrease or loss of the basicity, for example, any of onium salts described in Japanese Patent 3577743, JP-A-2001-215689, JP-A-2001-166476 and JP-A-2008-102383) and a photobasicity generator (for example, compounds described in JP-A-2010-243773).

One of these basic compounds (including compound (D)) may be used alone, or two or more thereof may be used in combination.

The amount of basic compound used, based on the solids of the composition, is generally in the range of 0.001 to 10 mass %, preferably 0.01 to 5 mass %.

The molar ratio of acid generator/basic compound is preferably in the range of 2.5 to 300. Namely, the molar ratio is preferred to be 2.5 or higher from the viewpoint of sensitivity and resolution, while the molar ratio is preferred to be 300 or below from the viewpoint of inhibiting any deterioration of resolution by thickening of pattern over time from exposure to baking treatment. This molar ratio is more preferably in the range of 5.0 to 200, further more preferably 7.0 to 150.

[5] Surfactant

The composition of the present invention may further comprise a surfactant. By virtue of the incorporation of a surfactant in the composition, a pattern ensuring diminished defects of adhesion and development can be formed with favorable sensitivity and resolution, in the event of using an exposure light source of wavelength 250 nm or shorter, especially 220 nm or shorter.

It is especially preferred to use a fluorinated and/or siliconized surfactant as the surfactant.

For example, use can be made of surfactants described in sections [0499] to [0505] of JP-A-2011-248019.

One of these surfactants may be used alone, or two or more thereof may be used in combination.

When the composition of the present invention contains a surfactant, the content thereof is preferably in the range of 0 to 2 mass %, more preferably 0.0001 to 2 mass % and further more preferably 0.0005 to 1 mass %, based on the total solids of the composition.

[6] Other Additive

The composition of the present invention can further appropriately comprise a carboxylic acid, a carboxylic acid onium salt, a dissolution inhibitor compound of 3000 or less molecular weight described in, for example, Proceeding of SPIE, 2724, 355 (1996), a dye, a plasticizer, a photosensitizer, a light absorber, an antioxidant, etc. other than the foregoing components.

In particular, the carboxylic acid can be appropriately used for performance enhancement. It is preferred for the carboxylic acid to be an aromatic carboxylic acid, such as benzoic acid or naphthoic acid.

The content of carboxylic acid, based on the total solids of the composition, is preferably in the range of 0.01 to 10 mass %, more preferably 0.01 to 5 mass % and further more preferably 0.01 to 3 mass %.

From the viewpoint of resolution enhancement, the actinic-ray- or radiation-sensitive resin composition of the present invention is preferably used in a film thickness of 10 to 250 nm. More preferably, the composition is used in a film thickness of 20 to 200 nm, further more preferably 30 to 100 nm. This film thickness can be attained by setting the solid content of the composition within an appropriate range so as to cause the composition to have an appropriate viscosity, thereby improving the applicability and film forming property.

The solid content of the actinic-ray- or radiation-sensitive resin composition according to the present invention is generally in the range of 1.0 to 10 mass %, preferably 2.0 to 5.7 mass % and more preferably 2.0 to 5.3 mass %. Not only can the resist solution be uniformly applied onto substrates but also a resist pattern excelling in line width roughness can be formed, by regulating the solid content so as to fall within the above range. The reason therefor has not been elucidated. However, it can be presumed that, by regulating the solid content at 10 mass % or less, preferably 5.7 mass % or less, any aggregation of materials, especially a photoacid generator, in the resist solution can be inhibited, resulting in the formation of a uniform resist film.

The solid content refers to the percentage of the weight of non-solvent resist components based on the total weight of the actinic-ray- or radiation-sensitive resin composition.

The actinic-ray- or radiation-sensitive resin composition of the present invention is used in such a manner that the above-mentioned components are dissolved in a given organic solvent, preferably the above-mentioned mixed solvent, filtered and applied onto a given support (substrate). The filter medium for use in the filtration is preferably one made of a polytetrafluoroethylene, polyethylene or nylon that has a pore size of 0.1 μm or less, preferably 0.05 μm or less and more preferably 0.03 μm or less. In the filtration, as described in, for example, JP-A-2002-62667, a cyclic filtration may be carried out, or multiple types of filters may be connected in series or parallel. Moreover, the composition may be filtered a plurality of times. Further, the composition may be, for example, deaerated prior to and/or after the filtration.

<Utility>

The actinic-ray- or radiation-sensitive resin composition of the present invention and the pattern forming method using the composition can find appropriate application in the fabrication of semiconductor microcircuits, for example, the manufacturing of a super-LSI or a high-capacity microchip. In the fabrication of semiconductor microcircuits, a patterned resist film is subjected to circuit formation and etching, and any resist film portions remaining thereafter are ultimately removed with a solvent, etc. Therefore, as opposed to a so-called permanent resist for use in printed boards, etc., no trace of the resist film derived from the actinic-ray- or radiation-sensitive resin composition according to the present invention is left on final products, such as microchips.

The present invention in its one aspect relates to an actinic-ray- or radiation-sensitive film comprising the actinic-ray- or radiation-sensitive resin composition. The actinic-ray- or radiation-sensitive film according to the present invention is typically an electron-beam- or extreme-ultraviolet-sensitive film.

<Pattern Forming Method>

Now, the pattern forming method of the present invention will be described.

The pattern forming method of the present invention comprises forming a film comprising the composition defined above, exposing the film to actinic rays or radiation (hereinafter also referred to as exposure to light) and developing the film having been exposed to actinic rays or radiation. It is preferred for the exposure to actinic rays or radiation to be performed using electron beams or extreme ultraviolet.

The pattern forming method of the present invention in its one mode comprises:

the operation of forming a film comprising an actinic-ray- or radiation-sensitive resin composition comprising (A) a resin containing an acid-decomposable repeating unit and having a solubility in developer comprising an organic solvent that is lowered when the resin is acted on by an acid and (B) a compound that is configured to produce an acid when exposed to actinic rays or radiation, wherein the acid produced by the compound that is configured to produce an acid when exposed to actinic rays or radiation exhibits a Log P value of 3.0 or below and has a molecular weight of 430 or greater,

the operation of exposing the film to electron beams or extreme ultraviolet, and

the operation of developing the film having been exposed to electron beams or extreme ultraviolet with a developer comprising an organic solvent to thereby obtain a negative pattern.

The operations performed in the pattern forming method will be sequentially described below.

(1) Film Formation

The resist film of the present invention is a film formed from the actinic-ray- or radiation-sensitive resin composition defined above.

In particular, the formation of the resist film can be accomplished by dissolving individual components of actinic-ray- or radiation-sensitive resin composition to be described hereinafter in a solvent, filtering the solution according to necessity and applying the solution onto a support (substrate). The filter used is preferably made of a polytetrafluoroethylene, polyethylene or nylon having a pore size of 0.1 μm or less, preferably 0.05 μm or less and more preferably 0.03 μm or less.

The composition is applied onto a substrate, such as one for use in the production of integrated circuit elements (e.g., silicon, silicon dioxide coating), by appropriate application means, such as a spin coater. Thereafter, the composition is dried, thereby obtaining a light-sensitive film. In the stage of drying, it is preferred to perform heating (prebaking).

The film thickness is not particularly limited. The film thickness is preferably regulated so as to fall within the range of 10 to 500 nm, more preferably 10 to 200 nm and further more preferably 10 to 80 nm. When the actinic-ray- or radiation-sensitive resin composition is applied by means of a spinner, the rotating speed thereof is generally in the range of 500 to 3000 rpm, preferably 800 to 2000 rpm and more preferably 1000 to 1500 rpm.

The heating (prebaking) is preferably performed at a temperature of 60 to 200° C., more preferably 80 to 150° C. and further more preferably 90 to 140° C.

The heating (prebaking) time is not particularly limited. The time is preferably in the range of 30 to 300 seconds, more preferably 30 to 180 seconds and further more preferably 30 to 90 seconds.

The heating can be performed by means provided in the common exposure/developing equipment. The heating can also be performed using a hot plate or the like.

According to necessity, a commercially available inorganic or organic antireflection film can be applied.

The antireflection film can be used by applying the same to an underlayer of the actinic-ray- or radiation-sensitive resin composition. As the antireflection film, use can be made of not only an inorganic film of titanium, titanium dioxide, titanium nitride, chromium oxide, carbon, amorphous silicon or the like but also an organic film comprised of a light absorbing agent and a polymer material. Also, as an organic antireflection film, use can be made of any of commercially available organic antireflection films, such as DUV-30 Series and DUV-40 Series produced by Brewer Science Inc. and AR-2, AR-3 and AR-5 produced by Shipley Co., Ltd.

(2) Exposure to Light

The exposure light source is not particularly limited. Preferably, the exposure is performed using extreme ultraviolet (EUV light) or electron beams (EB). When extreme ultraviolet (EUV light) is used as the exposure light source, the formed film is preferably exposed through a given mask to EUV light (near 13 nm). In the exposure using electron beams (EB), lithography through no mask (direct lithography) is generally carried out.

(3) Bake

It is preferred to perform baking (heating) after exposure but before development.

The heating temperature is preferably in the range of 60° to 150° C., more preferably 80° to 150° C. and further more preferably 90° to 140° C.

The heating time is not particularly limited. The time is preferably in the range of 30 to 300 seconds, more preferably 30 to 180 seconds and further more preferably 30 to 90 seconds.

The heating can be carried out by means provided in the common exposure/developing equipment and may also be carried out using a hot plate or the like.

The baking accelerates the reaction in exposed areas, thereby enhancing the sensitivity and pattern profile. Further, the rinsing operation is preferably followed by the operation of heating (PostBaking). The heating temperature and heating time are as described above. This baking removes any inter-pattern and intra-pattern remaining developer and rinse liquid.

(4) Development

Both a developer comprising an organic solvent (hereinafter also referred to as organic developer) and an alkali developer can be used as the developer. Using the organic developer is preferred.

When development is performed with a developer comprising an organic solvent, as the developer, use can be made of a polar solvent, such as a ketone solvent, an ester solvent, an alcohol solvent, an amide solvent or an ether solvent, and a hydrocarbon solvent. As particular examples of these solvents, there can be mentioned the developers set forth in sections 0633 to 0641 of US 2008/0187860A.

A plurality of these solvents may be mixed together before use. Alternatively, each of these solvents may be used in a mixture with a solvent other than those mentioned above or water. However, from the viewpoint of the fullest exertion of the effects of the present invention, it is preferred for the water content of the developer as a whole to be less than 10 mass %. More preferably, the developer contains substantially no trace of water.

The concentration of organic solvent (when a plurality of organic solvents are mixed together, the sum thereof) in the developer is preferably 50 mass % or greater, more preferably 70 mass % or greater and further more preferably 90 mass % or greater. Most preferably, the developer substantially consists only of an organic solvent. Substantially consisting only of an organic solvent refers to developers in which small amounts of surfactant, antioxidant, stabilizer, antifoamer, etc. may be contained.

As the organic developer, preferred use is made of a polar solvent, such as an ester solvent (butyl acetate, ethyl acetate or the like), a ketone solvent (2-heptanone, cyclohexanone or the like), an alcohol solvent, an amide solvent or an ether solvent, and a hydrocarbon solvent. More preferably, the organic developer comprises at least one member selected from the group consisting of butyl acetate, pentyl acetate, isopentyl acetate, propylene glycol monomethyl ether acetate and anisole.

It is preferred for the organic developer to comprise an ester solvent, especially butyl acetate.

The organic developer may comprise a basic compound. As particular examples of the basic compounds that can be contained in the organic developer, there can be mentioned those set forth above as examples of basic compounds that can be contained in the actinic-ray- or radiation-sensitive resin composition.

A quaternary ammonium salt whose representative is tetramethylammonium hydroxide is generally used in the alkali developer. Besides this, use can be made of an alkaline aqueous solution containing, for example, an inorganic alkali, a primary amine, a secondary amine a tertiary amine, an alcoholamine or a cycloamine.

Surfactant

According to necessity, an appropriate amount of surfactant can be added to the developer.

As the surfactant, use can be made of any of the same surfactants as employed in the actinic-ray- or radiation-sensitive resin composition, to be described hereinafter.

The amount of surfactant added is generally in the range of 0.001 to 5 mass %, preferably 0.005 to 2 mass % and more preferably 0.01 to 0.5 mass % based on the whole mass of the developer.

Developing Method

As the developing method, use can be made of, for example, any of a method in which the substrate is immersed in a tank filled with a developer for a given period of time (dip method), a method in which a developer is mounded on the surface of the substrate by its surface tension and allowed to stand still for a given period of time to thereby effect development (puddle method), a method in which a developer is sprayed onto the surface of the substrate (spray method), a method in which a developer is continuously discharged onto the substrate rotating at a given speed while scanning a developer discharge nozzle at a given speed (dynamic dispense method), and the like.

The developing operation may be followed by the operation of discontinuing the development by replacing the developer with another solvent.

The developing time is not particularly limited as long as it is enough to satisfactorily dissolve the resin remaining in unexposed areas. Generally, the developing time is in the range of 10 to 300 seconds. Preferably, the time is in the range of 20 to 120 seconds.

The temperature of the developer is preferably in the range of 0 to 50° C., more preferably 15 to 35° C.

(5) Rinse

In the pattern forming method of the present invention, the developing operation (4) may be followed by the operation (5) of rinsing with a rinse liquid. The rinse liquid for use in this operation may be an aqueous rinse liquid, or a rinse liquid comprising an organic solvent.

Rinse Liquid

With respect to the rinse liquid for use after the development, the vapor pressure thereof (when use is made of a solvent mixture, the vapor pressure of the entirety) at 20° C. is preferably in the range of 0.05 to 5 kPa, more preferably 0.1 to 5 kPa and most preferably 0.12 to 3 kPa. When the vapor pressure of the rinse liquid is in the range of 0.05 to 5 kPa, not only can the temperature uniformity within the plane of the wafer be enhanced but also any swell attributed to the penetration of the rinse liquid can be suppressed to thereby improve the dimensional uniformity within the plane of the wafer.

When an organic solvent is used as the rinse liquid, it is preferred to employ a rinse liquid comprising at least one organic solvent selected from among a hydrocarbon solvent, a ketone solvent, an ester solvent, an alcohol solvent, an amide solvent and an ether solvent. Also, it is preferred for the rinse liquid to be one comprising water.

The development is more preferably followed by the operation of rinsing with a rinse liquid comprising at least one organic solvent selected from among a ketone solvent, an ester solvent, an alcohol solvent, an amide solvent and a hydrocarbon solvent. Further more preferably, the development is followed by the operation of rinsing with a rinse liquid comprising an alcohol solvent or a hydrocarbon solvent.

Most preferably, use is made of a rinse liquid comprising at least one member selected from the group consisting of monohydric alcohols and hydrocarbon solvents.

As the monohydric alcohols for use in the rinsing operation after development, there can be mentioned linear, branched or cyclic monohydric alcohols. For example, use can be made of 1-butanol, 2-butanol, 3-methyl-1-butanol, tert-butyl alcohol, 1-pentanol, 2-pentanol, 1-hexanol, 1-heptanol, 1-octanol, 2-hexanol, 2-heptanol, 2-octanol, 3-hexanol, 3-heptanol, 3-octanol, 4-octanol, 3-methyl-3-pentanol, cyclopentanol, 2,3-dimethyl-2-butanol, 3,3-dimethyl-2-butanol, 2-methyl-2-pentanol, 2-methyl-3-pentanol, 3-methyl-2-pentanol, 4-methyl-2-pentanol, 4-methyl-3-pentanol, cyclohexanol, 5-methyl-2-hexanol, 4-methyl-2-hexanol, 4,5-dimethyl-2-hexanol, 6-methyl-2-heptanol, 7-methyl-2-octanol, 8-methyl-2-nonanol, 9-methyl-2-decanol and the like. Among these, 1-hexanol, 2-hexanol, 1-pentanol, 3-methyl-1-butanol, 3-methyl-2-pentanol, 3-methyl-3-pentanol, 4-methyl-2-pentanol and 4-methyl-3-pentanol are preferred. 1-Hexanol and 4-methyl-2-pentanol are most preferred.

As the hydrocarbon solvents, there can be mentioned an aromatic hydrocarbon solvent, such as toluene or xylene, and an aliphatic hydrocarbon solvent, such as octane or decane.

It is especially preferred for the rinse liquid to comprise at least one member selected from the group consisting of 1-hexanol, 4-methyl-2-pentanol and decane.

Two or more of these components may be mixed together before use. Also, they may be mixed with other organic solvents before use. These solvents may be mixed with water. However, the water content of the rinse liquid is generally 60 mass % or below, preferably 30 mass % or below, more preferably 10 mass % or below and most preferably 5 mass % or below. Favorable rinsing performance can be attained by controlling the water content at 60 mass % or below.

An appropriate amount of surfactant can be added to the rinse liquid before use.

The surfactant can be the same as used in the actinic-ray- or radiation-sensitive resin composition to be described hereinafter. The amount of surfactant used is generally in the range of 0.001 to 5 mass %, preferably 0.005 to 2 mass % and further more preferably 0.01 to 0.5 mass % based on the whole mass of the rinse liquid.

Rinse Method

In the rinse operation, the wafer having undergone development is rinsed with the above-mentioned rinse liquid comprising an organic solvent.

The method of rinsing is not particularly limited. For example, use can be made of any of a method in which the rinse liquid is continuously discharged onto the substrate being rotated at a given speed (spin discharge method), a method in which the substrate is dipped in a tank filled with the rinse liquid for a given period of time (dip method), a method in which the rinse liquid is sprayed onto the surface of the substrate (spray method), etc. Preferably, the rinsing is carried out in accordance with the spin discharge method, and thereafter the substrate is rotated at a rotating speed of 2000 to 4000 rpm to thereby remove the rinse liquid from the top of the substrate.

The rinsing time is not particularly limited. Generally, the rinsing time is in the range of 10 to 300 seconds. The rinsing time is preferably in the range of 10 to 180 seconds, most preferably 20 to 120 seconds.

The temperature of the rise liquid is preferably in the range of 0 to 50° C., more preferably 15 to 35° C.

Further, the developing operation or rinsing operation may be followed by the operation of removing any portion of developer or rinse liquid adhering onto the pattern by the use of a supercritical fluid.

Still further, the developing operation, or rinsing operation, or operation with a supercritical fluid may be followed by the baking operation for removing any solvent remaining in the pattern. The baking temperature is not particularly limited as long as a favorable resist pattern can be obtained. Generally, the baking temperature is in the range of 40 to 160° C. The baking temperature is preferably in the range of 50 to 150° C., most preferably 50 to 110° C. The baking time is not particularly limited as long as a favorable resist pattern can be obtained. Generally, the baking time is in the range of 15 to 300 seconds. The baking time is preferably in the range of 15 to 180 seconds.

Alkali Development

The pattern forming method of the present invention can comprise the operation (alkali developing operation) of, after the development with an organic developer, further developing with an alkaline aqueous solution to thereby obtain a resist pattern. As a result, finer patterns can be formed.

In the present invention, not only can areas of low light exposure intensity be removed by the operation of organic solvent development, but also areas of high light exposure intensity can be removed by further performing the operation of alkali development. Pattern formation can be carried out without dissolution of only areas of intermediate light exposure intensity by this multiple developing process in which development is performed a plurality of times, so that patterns finer than usual can be formed (the same mechanism as in section [0077] of JP-A-2008-292975).

The alkali development can be performed before or after, whichever appropriate, the operation of developing with a developer comprising an organic solvent. The alkali development is preferably performed before the operation of organic solvent development.

The alkaline aqueous solution that can be used in the alkali development is, for example, an alkaline aqueous solution containing an inorganic alkali, such as sodium hydroxide, potassium hydroxide, sodium carbonate, sodium silicate, sodium metasilicate or aqueous ammonia; a primary amine, such as ethylamine or n-propylamine; a secondary amine, such as diethylamine or di-n-butylamine; a tertiary amine, such as triethylamine or methyldiethylamine; an alcoholamine, such as dimethylethanolamine or triethanolamine; a quaternary ammonium salt, such as tetramethylammonium hydroxide or tetraethylammonium hydroxide; a cycloamine, such as pyrrole or piperidine; or the like.

Appropriate amounts of alcohol and surfactant may further be added to the above alkaline aqueous solution before use.

The alkali concentration of the alkali developer is generally in the range of 0.1 to 20 mass %.

The pH value of the alkali developer is generally in the range of 10.0 to 15.0.

A 2.38 mass % aqueous tetramethylammonium hydroxide solution is especially preferred.

The time of alkali development is not particularly limited. Generally, the time of alkali development is in the range of 10 to 300 seconds. The time is preferably in the range of 20 to 120 seconds.

The temperature of the alkali developer is preferably in the range of 0 to 50° C., more preferably 15 to 35° C.

The development with an alkaline aqueous solution may be followed by a rinsing operation. The rinse liquid for use in the rinsing operation is preferably pure water. An appropriate amount of surfactant can be added thereto before use.

Further, the developing operation or rinsing operation may be followed by a baking operation intended to remove any water remaining in the pattern.

The operation of removing any remaining developer or rinse liquid by baking can be performed. The baking temperature is not particularly limited as long as a favorable resist pattern can be obtained. Generally, the baking temperature is in the range of 40 to 160° C. The baking temperature is preferably in the range of 50 to 150° C., most preferably 50 to 110° C. The baking time is not particularly limited as long as a favorable resist pattern can be obtained. Generally, the baking time is in the range of 15 to 300 seconds. The baking time is preferably in the range of 15 to 180 seconds.

In the stage of exposing the film formed from the composition of the present invention to electron beams or extreme ultraviolet, the exposure (liquid immersion exposure) may be carried out after filling the interstice between the film and a lens with a liquid (liquid immersion medium) of refractive index higher than that of air. This enhances the resolution. The liquid immersion medium for use is not particularly limited as long as it is a liquid whose refractive index is higher than that of air. Pure water is preferred.

Lithography performance can be enhanced by raising the refractive index of the immersion liquid. From this viewpoint, an additive suitable for refractive index increase may be added to water, or heavy water (D₂O) may be used in place of water.

For the prevention of direct contact of the film with the immersion liquid, a film that is highly insoluble in the immersion liquid (hereinafter also referred to as “top coat”) may be provided between the film from the composition of the present invention and the immersion liquid. The required functions of the top coat are applicability to an upper layer portion of the composition film and high insolubility in the immersion liquid. It is preferred for the top coat to be immiscible with the composition film and to be uniformly applicable to an upper layer of the composition film.

As the top coat, there can be mentioned, for example, one comprised of a hydrocarbon polymer, an acrylic ester polymer, polymethacrylic acid, polyacrylic acid, polyvinyl ether, a siliconized polymer, a fluoropolymer or the like. When impurities are leached from the top coat into the immersion liquid, the optical lens is stained. From this viewpoint, it is preferred to reduce the amount of residual monomer components of polymer contained in the top coat.

When the top coat is detached, use may be made of a developer, or a separate peeling agent. The peeling agent is preferably comprised of a solvent exhibiting a lower permeation into the film. Detachability by a developer comprising an organic solvent is preferred from the viewpoint that the detaching operation can be performed simultaneously with the development processing operation for the film.

The less the difference in refractive index between the top coat and the immersion liquid, the higher the resolution. When water is used as the immersion liquid, it is preferred for the top coat to have a refractive index close to that of the immersion liquid. From the viewpoint of allowing the refractive index to be close to that of the immersion liquid, it is preferred to introduce a fluorine atom in the top coat. Moreover, from the viewpoint of transparency and refractive index, it is preferred to reduce the thickness of the film.

It is preferred for the top coat to be immiscible with not only the film but also the immersion liquid. From this viewpoint, when the immersion liquid is water, it is preferred for the solvent for use in the top coat to be highly insoluble in the solvent for use in the composition of the present invention and to be a water-insoluble medium. When the immersion liquid is an organic solvent, the top coat may be water-soluble or water-insoluble, whichever appropriate.

Furthermore, the present invention relates to a process for manufacturing an electronic device in which the above-described pattern forming method of the present invention is included, and relates to an electronic device manufactured by the process.

The electronic device of the present invention can be appropriately mounted in electrical and electronic equipments (household electronic appliance, OA/media-related equipment, optical apparatus, telecommunication equipment and the like).

### EXAMPLES

The present invention will be described in greater detail below by way of its examples. However, the gist of the present invention is in no way limited to these examples.

### Synthetic Example 1

### Synthesis of Resin (P-1)

Resin (P-1) was synthesized in accordance with the following scheme.

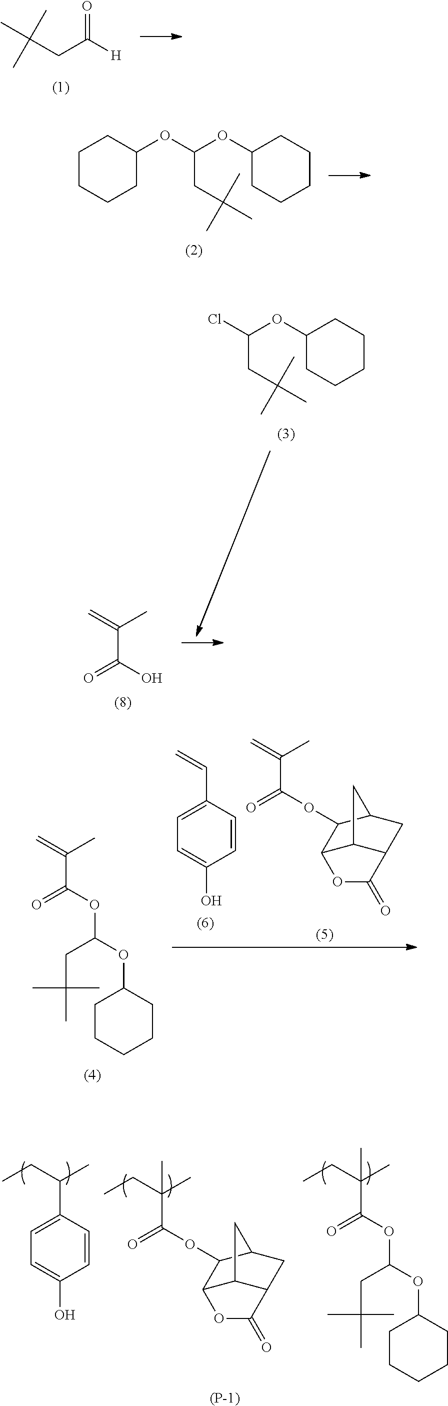

Compound (1) amounting to 20.00 g was dissolved in 113.33 g of n-hexane. Cyclohexanol amounting to 42.00 g, 20.00 g of anhydrous magnesium sulfate and 2.32 g of camphor-10-sulfonic acid were added to the solution, and agitated at room temperature (25° C.) for 7.5 hours. Triethylamine amounting to 5.05 g was added, agitated for 10 minutes and filtered, thereby removing any solid. Ethyl acetate amounting to 400 g was added, and the thus obtained organic phase was washed with 200 g of ion-exchange water five times. The washed organic phase was dried over anhydrous magnesium sulfate, and any solvent was distilled off. As a result, a solution containing compound (2) was obtained in an amount of 44.86 g.

Acetyl chloride amounting to 4.52 g was added to 23.07 g of solution containing compound (2), and agitated at room temperature for 2 hours. As a result, a solution containing compound (3) was obtained in an amount of 27.58 g.

Compound (8) amounting to 3.57 g was dissolved in 26.18 g of dehydrated tetrahydrofuran. Anhydrous magnesium sulfate amounting to 3.57 g and 29.37 g of triethylamine were added to the solution, and agitated in a nitrogen atmosphere. The mixture was cooled to 0° C., and 27.54 g of solution containing compound (3) was dropped thereinto. The mixture was agitated at room temperature for 3.5 hours, and filtered, thereby removing any solid. Ethyl acetate amounting to 400 g was added, and the thus obtained organic phase was washed with 150 g of ion-exchange water five times. The washed organic phase was dried over anhydrous magnesium sulfate, and any solvent was distilled off. Through isolation and purification by gas chromatography, there was obtained 8.65 g of compound (4).

A cyclohexanone solution (50.00 mass %) of 2.52 g of compound (6) together with 0.78 g of compound (5), 5.64 g of compound (4) and 0.32 g of polymerization initiator V-601 (produced by Wako Pure Chemical Industries, Ltd.) were dissolved in 27.01 g of cyclohexanone. Cyclohexanone amounting to 15.22 g was placed in a reaction vessel, and in a nitrogen gas atmosphere, the solution was dropped into the reaction system heated at 85° C. over a period of 4 hours. The thus obtained reaction solution was agitated while heating for two hours, and allowed to stand still to cool to room temperature.

The resultant reaction solution was dropped into 400 g of heptane, thereby precipitating a polymer, and filtered. The solid obtained by filtration was showered with 200 g of heptane. Thereafter, the showered solid was dried in vacuo. As a result, 2.98 g of resin (P-1) was obtained.

[Pattern Formation; Exposure to Extreme Ultraviolet (EUV)]

(1) Preparation of Coating Solution of Actinic-Ray- or Radiation-Sensitive Resin Composition and Application Thereof

Each of the coating solution compositions each of 2.5 mass % solid content (Examples 1 to 8 and Comparative Examples 1 to 3) whose individual components were indicated in Table 2 below was precision filtered through a membrane filter of 0.05 μm pore diameter, thereby obtaining a solution of actinic-ray- or radiation-sensitive resin composition (resist composition).

Each of the obtained actinic-ray- or radiation-sensitive resin compositions was applied onto a 6-inch Si wafer having been treated with hexamethyldisilazane (HMDS) by means of a spin coater Mark 8 manufactured by Tokyo Electron Limited, and dried on a hot plate at 100° C. for 60 seconds, thereby obtaining a 50 nm-thick resist film.

Subsequently, an upper-layer film was formed by the same spin coating.

(2) Exposure to EUV and Development

Each of the wafers coated with resist films that were obtained in section (1) above was patternwise exposed through an exposure mask (line/space=4/1) to EUV by means of an EUV exposure apparatus (Micro Exposure Tool manufactured by Exitech Limited, NA0.3, X-dipole, outer sigma 0.68, inner sigma 0.36). Each of the exposed wafers was baked on a hot plate at 110° C. for 60 seconds, developed for 30 seconds by puddling the organic developer indicated in Table 2, and rinsed with the rinse liquid indicated in Table 2. Thereafter, the rinsed wafer was rotated at a rotating speed of 4000 rpm for 30 seconds and baked at 90° C. for 60 seconds. As a result, resist patterns each of a line/space=4:1 isolated space were obtained.

(3) Evaluation of Resist Pattern

Each of the thus obtained resist patterns was evaluated with respect to the line width roughness, resolution and top roughness in accordance with the following methods using a scanning electron microscope (model S-9380II manufactured by Hitachi, Ltd.).

(3-1) Line Width Roughness

The sensitivity (Eop) was defined as the exposure energy in which a pattern of 40 nm line width and line/space=1:1 was resolved. The smaller this value, the more favorable the performance exhibited.

A 50 nm line width 1:1 line and space pattern was formed in the exposure amount exhibiting the above sensitivity. At arbitrary 30 points within 50 μm in the longitudinal direction of the pattern, the distance between actual edge and a reference line on which edges were to be present was measured by means of a scanning electron microscope (model S-9220, manufactured by Hitachi, Ltd.). The standard deviation of measured distances was determined, and 3σ was computed therefrom. The smaller the value thereof, the more favorable the performance exhibited.

(3-2) Resolution of Isolated Space

The limiting resolving power (minimum space width permitting the separation and resolution of a line and a space) of isolated space (line/space=4:1) was determined at the above Eop. This value was denoted as the “resolution (nm).” The smaller the value, the better the performance exhibited.

(3-3) Top Roughness

With respect to each of the obtained resist patterns, an SEM micrograph of its cross section was obtained. The asperity of each pattern top surface (not pattern side walls) was visually observed. Evaluation mark A was given when the surface roughness is slight, and evaluation mark B was given when the surface roughness is intense.

The individual components employed in Examples and Comparative Examples are listed below.

[Resin (A)]

The following resins (P-2) and (P-6) were produced and used in the same manner as described above with respect to resin (P-1). The structures of resins (P-1) to (P-6) and the component ratios (Table 1) of each of the resins are shown below (the positional relationship of individual repeating units of each of the resins corresponds to the positional relationship of component ratio numeric values in Table 1). In Table 1, Mw refers to the weight average molecular weight, and Mw/Mn refers to the polydispersity index.

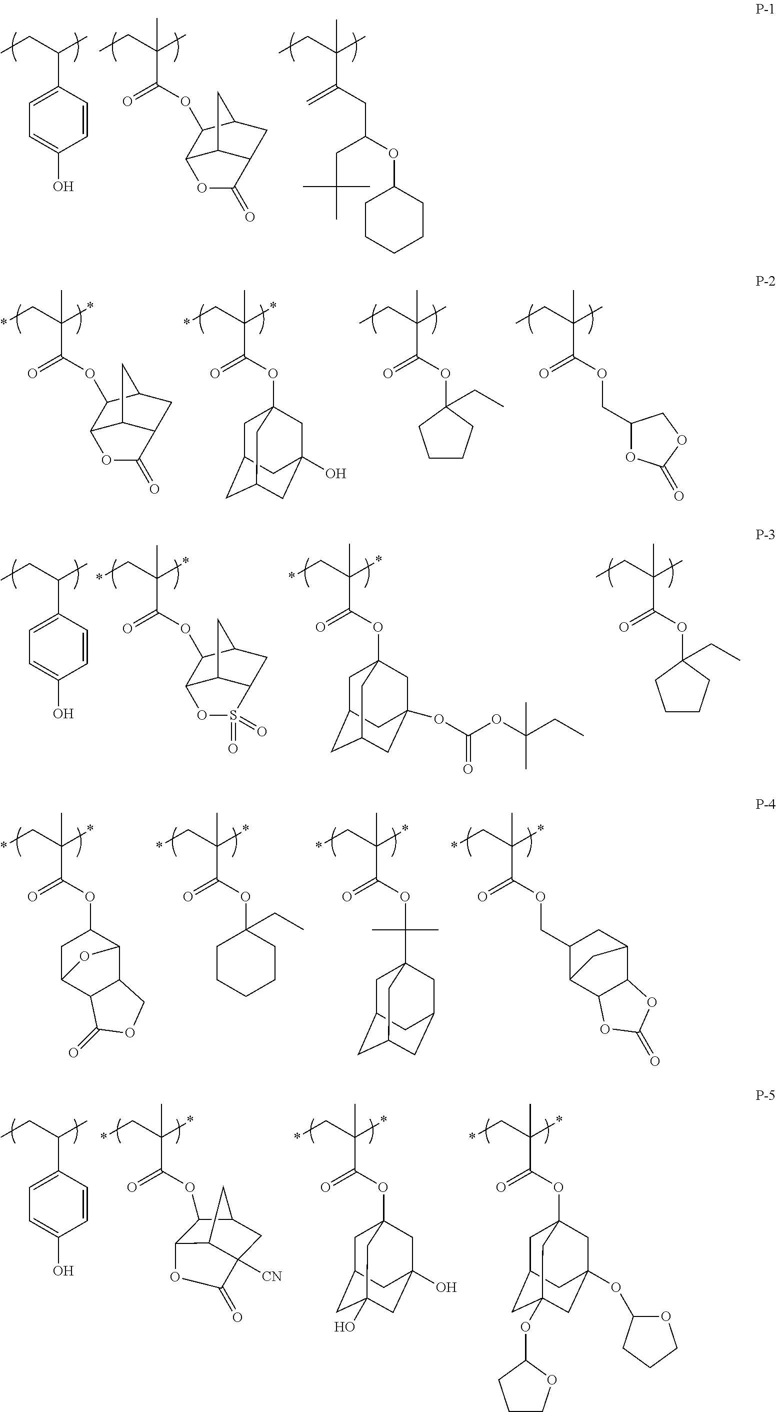

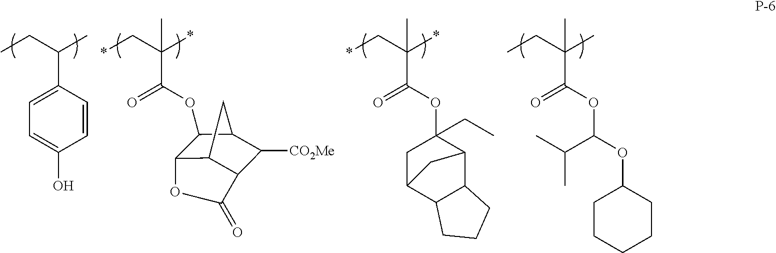

TABLE 1

| Resin | Mw | Mw/Mn | Composition ratio | | | |
|---|---|---|---|---|---|---|
| P-1 | 11000 | 1.42 | 30 | 10 | 60 | |
| P-2 | 10500 | 1.60 | 35 | 10 | 45 | 10 |
| P-3 | 7200 | 1.55 | 35 | 15 | 20 | 30 |
| P-4 | 11500 | 1.71 | 30 | 40 | 10 | 20 |
| P-5 | 7100 | 1.56 | 40 | 10 | 5 | 45 |
| P-6 | 11000 | 1.77 | 40 | 10 | 20 | 30 |

[Acid Generator (B)]

As the acid generator, at least one member was appropriately selected from among the following compounds and used. In the following, the Log P value refers to the Log P value of the acid produced by the acid generator, and the value of Mw refers to the molecular weight of the acid produced by the acid generator.

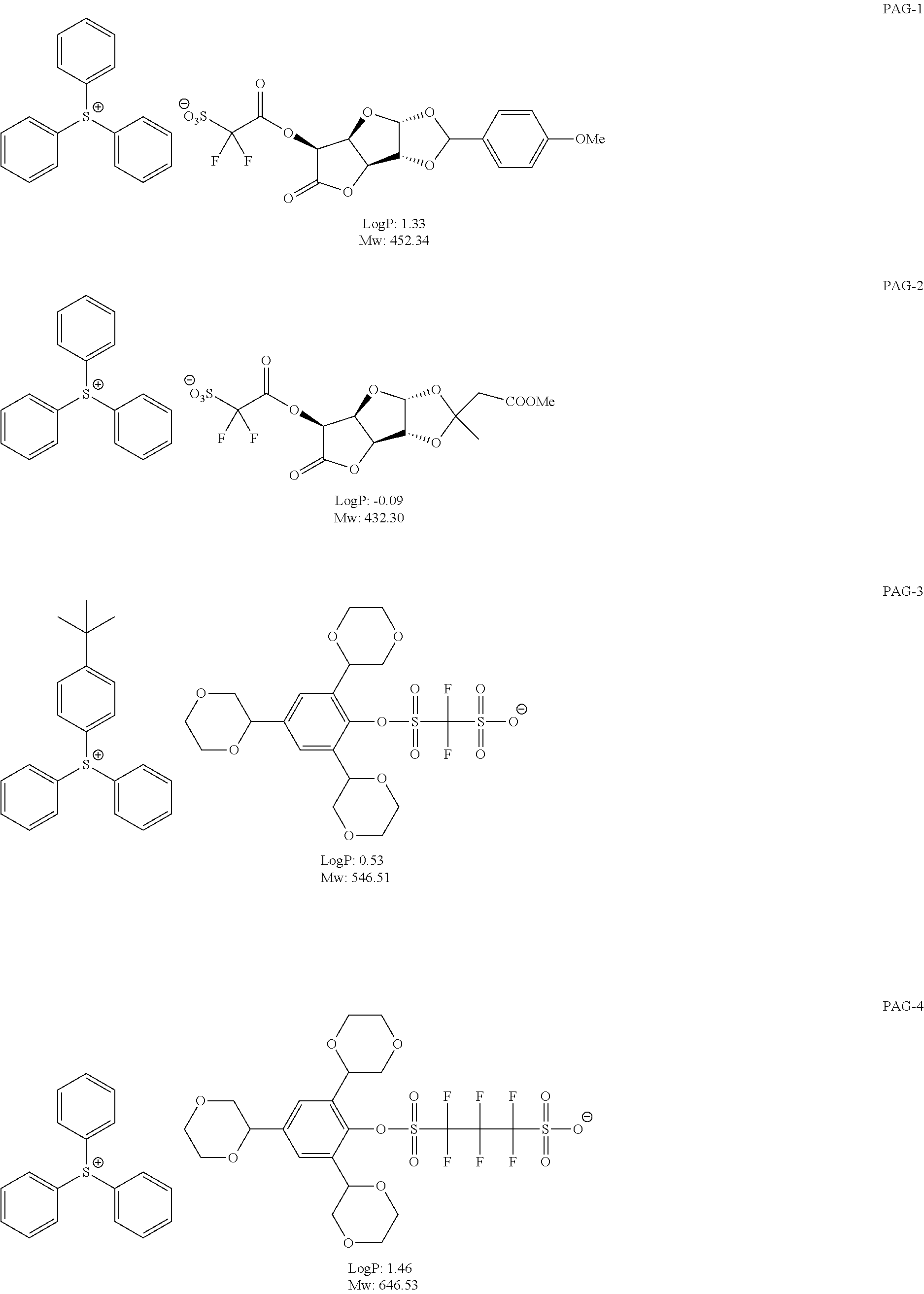

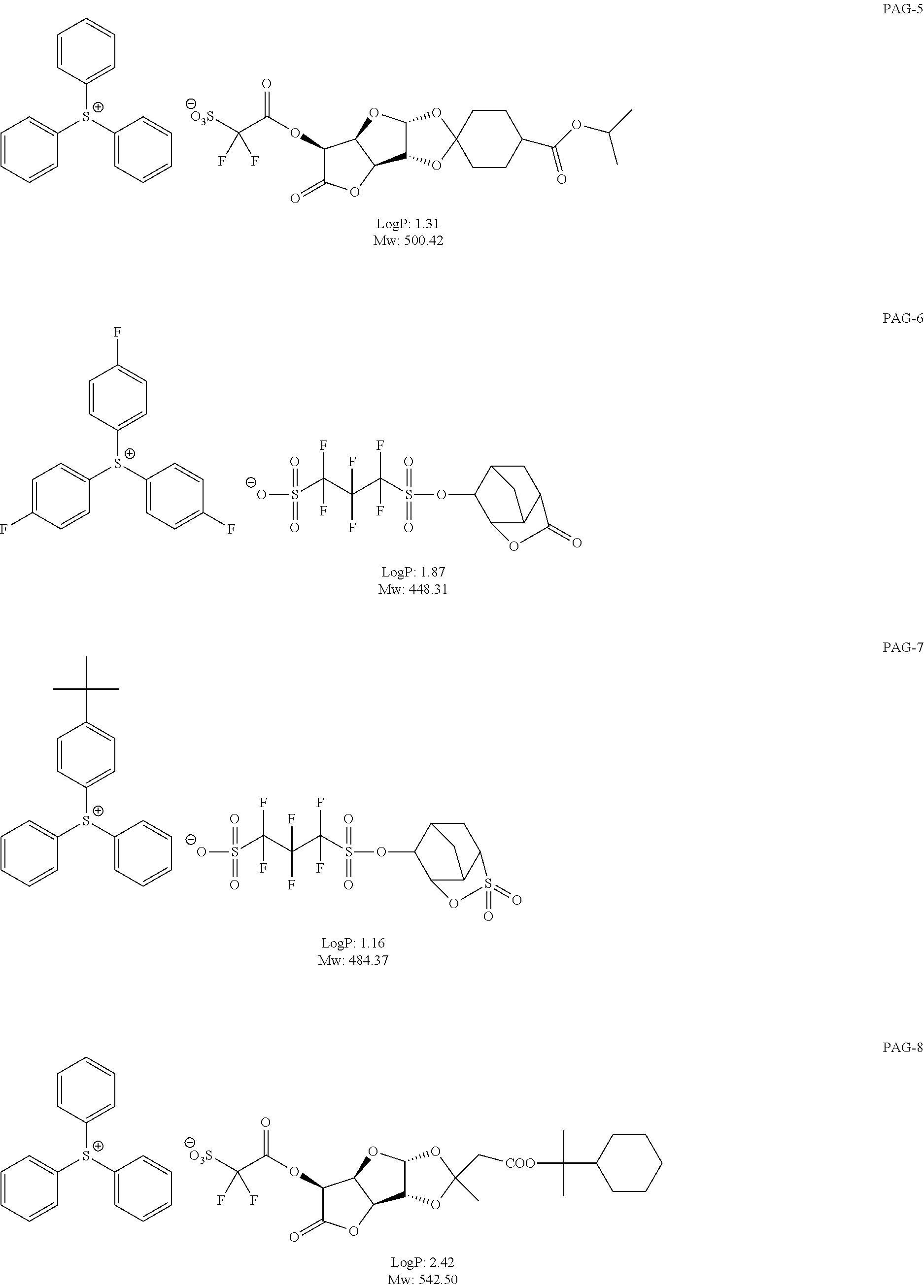

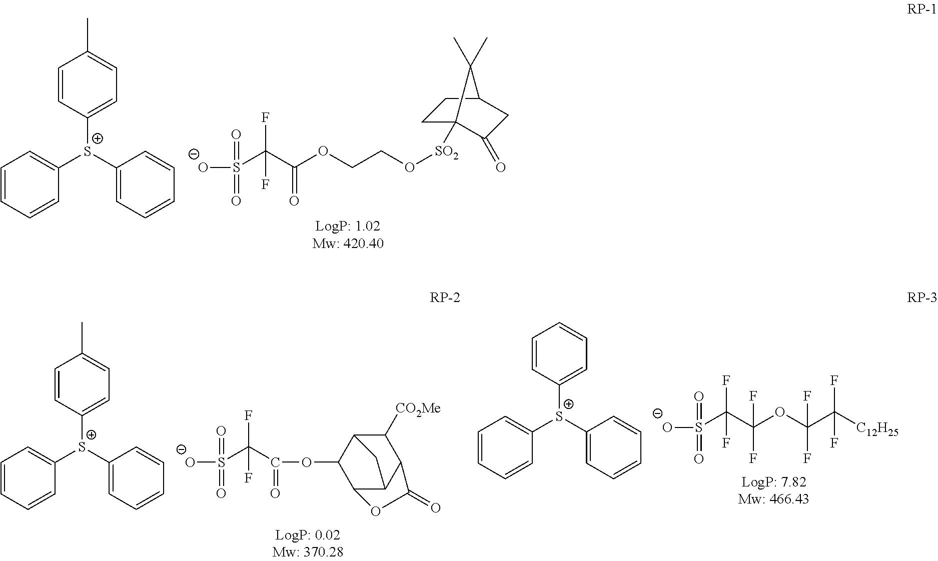

[Basic Compound]

The following compounds N-1 to N-10 were used individually or in combination as the basic compound.

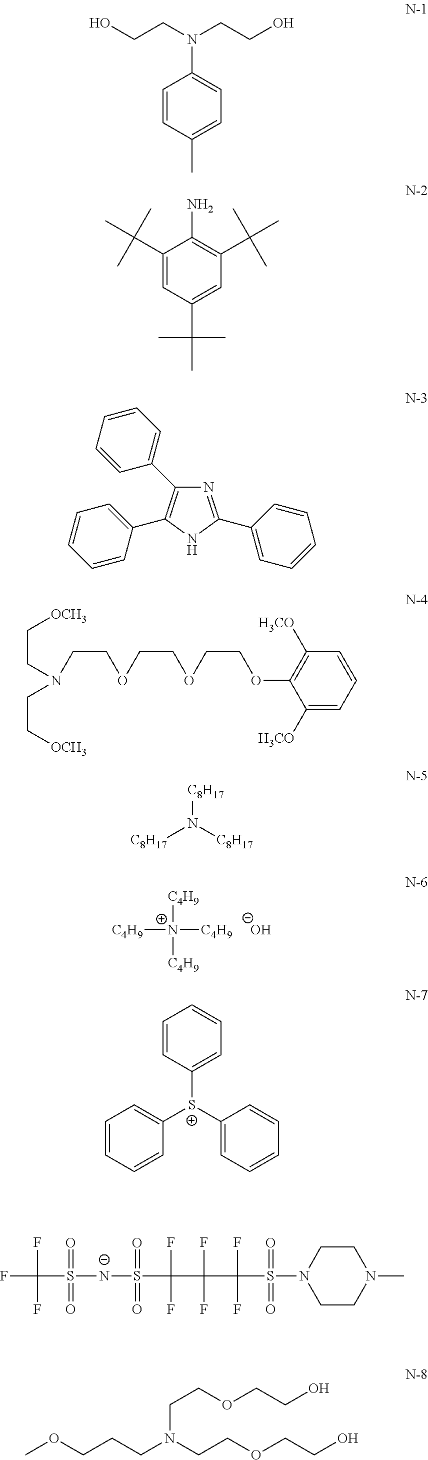

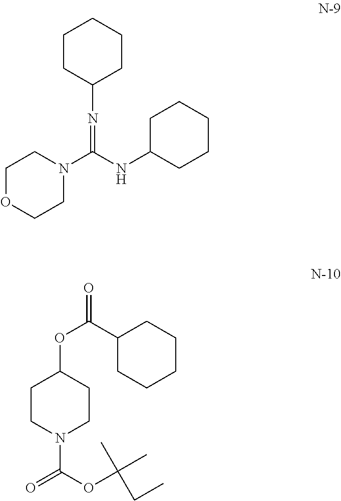 [SMILES: C1CCC(N=C(NC2CCCCC2)N2CCOCC2)CC1 ; CCC(C)(C)OC(=O)N1CCC(OC(=O)C2CCCCC2)CC1]

Compound N-7 above was synthesized in accordance with the description in section [0354] of JP-A-2006-330098.

[Surfactant]

Use was made of the following surfactants W-1 to W-4.

W-1: Megafac F176 (produced by DIC Corporation) (fluorinated),

W-2: Megafac R08 (produced by DIC Corporation) (fluorinated and siliconized),

W-3: polysiloxane polymer KP-341 (produced by Shin-Etsu Chemical Co., Ltd.)(siliconized), and

W-4: PF6320 (produced by OMNOVA SOLUTIONS, INC.)(fluorinated).

[Solvent]

The following solvents were used.

S1: propylene glycol monomethyl ether acetate (PGMEA),

S2: propylene glycol monomethyl ether (PGME),

S3: ethyl lactate,

S4: cyclohexanone, and

S5: γ-butyrolactone.

[Developer]

The following developer was used.

SG-3: butyl acetate.

[Rinse Liquid]

The following rinse liquids were used.

SR-1: 4-methyl-2-pentanol,

SR-2: 1-hexanol, and

SR-3: methyl isobutyl carbinol.

The evaluation results of the resist compositions of the present invention are listed in Table 2 below.

TABLE 2

| | Resin (A) | | | | Acid generator (B) | | | | Basic compd | | | |
|---|---|---|---|---|---|---|---|---|---|---|---|---|
| | Compd | Part by | Compd | Part by | Compd | Part by | Compd | Part by | Compd | Part by | Compd | Part by |
| | No. | mass | No. | mass | No. | mass | No. | mass | No. | mass | No. | mass |
| Ex. 1 | P-1 | 77.99 | | | PAG-1 | 20.0 | | | N-6 | 2.00 | | |
| Ex. 2 | P-1 | 77.99 | | | PAG-2 | 20.0 | | | N-6 | 2.00 | | |
| Ex. 3 | P-2 | 64.69 | | | PAG-8 | 15.0 | PAG-2 | 18.0 | N-1 | 1.50 | N-3 | 0.80 |
| Ex. 4 | P-3 | 66.23 | | | PAG-3 | 15.0 | PAG-4 | 16.5 | N-6 | 1.50 | N-2 | 0.75 |
| Ex. 5 | P-4 | 65.70 | | | PAG-6 | 19.0 | PAG-1 | 12.0 | N-7 | 3.00 | N-4 | 0.30 |
| Ex. 6 | P-5 | 66.15 | | | PAG-4 | 19.0 | PAG-6 | 12.0 | N-10 | 2.50 | N-5 | 0.30 |
| Ex. 7 | P-6 | 66.00 | | | PAG-5 | 18.0 | PAG-8 | 14.0 | N-9 | 1.00 | N-8 | 1.00 |
| Ex. 8 | P-1 | 34.08 | P-2 | 30.0 | PAG-7 | 20.0 | PAG-2 | 13.5 | N-7 | 2.00 | N-6 | 0.40 |
| Comp. Ex. 1 | P-1 | 77.99 | | | RP-1 | 20.0 | | | N-6 | 2.00 | | |
| Comp. Ex. 2 | P-1 | 77.99 | | | RP-2 | 20.0 | | | N-6 | 2.00 | | |
| Comp. Ex. 3 | P-1 | 77.99 | | | RP-3 | 20.0 | | | N-6 | 2.00 | | |

| | Surfactant | | Solvent | | | | | |
|---|---|---|---|---|---|---|---|---|
| | Compd | Part by | | Part by | | Part by | | Part by |
| | No. | mass | Solv. 1 | mass | Solv. 2 | mass | Solv. 3 | mass |
| Ex. 1 | W-1 | 0.01 | S1 | 2340 | S2 | 1170 | S4 | 390 |
| Ex. 2 | W-1 | 0.01 | S1 | 2340 | S2 | 1170 | S4 | 390 |
| Ex. 3 | W-2 | 0.01 | S1 | 1800 | S3 | 1100 | S4 | 1000 |
| Ex. 4 | W-4 | 0.02 | S1 | 2100 | S3 | 800 | S4 | 1000 |
| Ex. 5 | | | S1 | 2700 | S3 | 1000 | S5 | 200 |
| Ex. 6 | W-4 | 0.05 | S1 | 2700 | S3 | 1000 | S5 | 200 |
| Ex. 7 | | | S1 | 2400 | S2 | 1200 | S5 | 300 |
| Ex. 8 | W-3 | 0.02 | S1 | 2400 | S2 | 1200 | S5 | 300 |
| Comp. Ex. 1 | W-1 | 0.01 | S1 | 2340 | S2 | 1170 | S4 | 390 |
| Comp. Ex. 2 | W-1 | 0.01 | S1 | 2340 | S2 | 1170 | S4 | 390 |
| Comp. Ex. 3 | W-1 | 0.01 | S1 | 2340 | S2 | 1170 | S4 | 390 |

| | | | Evaluation | | |
|---|---|---|---|---|---|
| | | Rinse | LWR | Resolution | Top |
| | Developer | liquid | (nm) | (nm) | roughness |
| Ex. 1 | SG-3 | | 3.4 | 28 | A |
| Ex. 2 | SG-3 | | 3.3 | 29 | A |
| Ex. 3 | SG-3 | | 3.0 | 28 | A |
| Ex. 4 | SG-3 | SR-3 | 2.8 | 26 | A |
| Ex. 5 | SG-3 | | 3.2 | 29 | A |
| Ex. 6 | SG-3 | | 2.8 | 27 | A |
| Ex. 7 | SG-3 | SR-1 | 2.8 | 27 | A |
| Ex. 8 | SG-3 | SR-2 | 3.0 | 29 | A |
| Comp. Ex. 1 | SG-3 | | 4.7 | 35 | B |
| Comp. Ex. 2 | SG-3 | | 4.5 | 36 | B |
| Comp. Ex. 3 | SG-3 | | 5.2 | 33 | B |

It is apparent from Table 2 above that patterns excelling in the LWR, resolution and top roughness can be obtained by the pattern forming method of the present invention. Even when electron beams were used as the exposure light source, results similar to those when EUV was used as the exposure light source were obtained.

What is claimed is:

1. An actinic-ray- or radiation-sensitive resin composition comprising:
(A) a resin containing an acid-decomposable repeating unit and having a polarity that is changed when the resin is acted on by an acid, and
(B) a compound that is configured to produce an acid when exposed to actinic rays or radiation,
wherein the acid produced by the compound (B) that is configured to produce an acid when exposed to actinic rays or radiation exhibits a Log P value of 3.0 or below and has a molecular weight of 430 or greater.

2. The actinic-ray- or radiation-sensitive resin composition according to claim 1, wherein the resin (A) further contains a repeating unit containing a polar group.

3. The actinic-ray- or radiation-sensitive resin composition according to claim 2, wherein the polar group is selected from among a hydroxyl group, a cyano group, a lactone group, a carboxylic acid group, a sulfonic acid group, an amide group, a sulfonamide group, an ammonium group, a sulfonium group and a group comprised of a combination of two or more of these.

4. The actinic-ray- or radiation-sensitive resin composition according to claim 1, wherein the resin (A) further contains a repeating unit containing an acid group.

5. The actinic-ray- or radiation-sensitive resin composition according to claim 4, wherein the acid group is any of a phenolic hydroxyl group, a carboxylic acid group, a sulfonic acid group, a fluoroalcohol group, a sulfonamide group, a sulfonylimide group, an (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group and a tris(alkylsulfonyl)methylene group.

6. The actinic-ray- or radiation-sensitive resin composition according to claim 1, wherein the resin (A) contains any of repeating units of general formula (I) below: 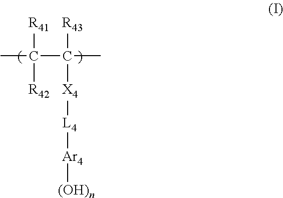
in which
each of R₄₁, R₄₂ and R₄₃ independently represents a hydrogen atom, an alkyl group, a halogen atom, a cyano group or an alkoxycarbonyl group, provided that R₄₂ may be bonded to Ar₄ to thereby form a ring, which R₄₂ represents a single bond or an alkylene group;
X₄ represents a single bond, —COO— or —CONR₆₄— in which R₆₄ represents a hydrogen atom or an alkyl group;
L₄ represents a single bond or an alkylene group;
Ar₄ represents a (n+1)-valent aromatic ring group, provided that when Ar₄ is bonded to R₄₂ to thereby form a ring, Ar₄ represents a (n+2)-valent aromatic ring group; and
n is an integer of 1 to 4.

7. The actinic-ray- or radiation-sensitive resin composition according to claim 6, wherein the repeating units of general formula (I) are contained in the resin (A) in an amount of 4 mol % or less based on all the repeating units of the resin (A).

8. The actinic-ray- or radiation-sensitive resin composition according to claim 1, wherein the Log P value exhibited by the acid produced by the compound (B) is in the range of −2.0 to 1.5.

9. An actinic-ray- or radiation-sensitive film comprising the actinic-ray- or radiation-sensitive resin composition of claim 1.

10. A method of forming a pattern, comprising forming a film comprising the composition of claim 1, exposing the film to actinic rays or radiation, and developing the film having been exposed to actinic rays or radiation.

11. The pattern forming method according to claim 10, wherein the exposure to actinic rays or radiation is performed using electron beams or extreme ultraviolet.

12. The pattern forming method according to claim 10, wherein the development is performed with a developer comprising an organic solvent.

13. The pattern forming method according to claim 10, used to fabricate a semiconductor nanocircuit.

14. A process for manufacturing an electronic device, comprising the pattern forming method of claim 10.

15. An electronic device manufactured by the process for manufacturing an electronic device according to claim 14.
